(19) United States
(12) Patent Application Publication
(10) Pub. No.: US 2026/0282764 A1
(43) Pub. Date: Sep. 17, 2026

(54) SUBSTRATE STRUCTURE AND METHOD FOR FABRICATING A SUBSTRATE STRUCTURE

(71) Applicant: Fraunhofer-Gesellschaft zur Foerderung der angewandten Forschung e.V., Munich (DE)

(72) Inventors: Hannes BENDER, Muenchen (DE); Lars NEBRICH, Muenchen (DE); Ignaz EISELE, Muenchen (DE); Andreas DROST, Muenchen (DE); Wilfried LERCH, Muenchen (DE); Karl NEUMEIER, Muenchen (DE)

(21) Appl. No.: 19/567,642

(22) Filed: Mar. 16, 2026

Related U.S. Application Data
(60) Provisional application No. 63/772,168, filed on Mar. 14, 2025.

(51) Int. Cl. H10N 69/00; H10N 60/01; H10W 72/00

(52) U.S. Cl. CPC H10N 69/00; H10N 60/01; H10W 72/07332

(57) ABSTRACT

A method for fabricating a substrate structure has: providing a stack structure having a first substrate, a plastically deformable superconductor layer, and a second substrate, the first substrate having a main surface with a topographic structure and the second substrate having a main surface facing the main surface of the first substrate, wherein the first substrate main surface has a structured superconductor metallization and the second substrate main surface has a structured superconductor metallization, wherein the plastically deformable superconductor layer extends between the structured superconductor metallization of the first substrate and the structured superconductor metallization of the second substrate, and—exerting pressure to the first and second substrates for compressing the plastically deformable superconductor layer between the structured superconductor metallizations of the first and second substrates to form a mechanical and electrical superconductor connection between the structured superconductor metallizations of the first and second substrates.

### CROSS-REFERENCE TO RELATED APPLICATION

This application claims priority form U.S. Provisional Application No. 63/772,168, which was filed on Mar. 14, 2025, and is incorporated herein by reference in its entirety.

### TECHNICAL FIELD

The present disclosure describes a substrate structure and a method for fabricating such a substrate structure. More specifically, embodiments of the present disclosure relate to a topographically structured substrate structure, e.g. a structured silicon substrate, for providing a metallization and contacting of superconducting quantum devices.

### BACKGROUND OF THE INVENTION

Currently, conductor paths and crossings of conductor paths have been created using “sacrificial” technologies (photoresist etc.). For single-chip solutions, the distances can therefore only be set to a limited extent. Capacitive couplings between conductor paths have so far taken place laterally and are defined using lithography processes. This requires space and is not suitable for further area-based scaling of qubits.

FIG. 13a shows a conventional device 200, e.g., with a superconducting connection option between two connection partners 210, 220 (here: e.g. chips 210, 220). The superconducting connections between these chips 210, 220 have so far been realized using metallic wire bonds 202, among other things (FIG. 13a). For the mechanical stabilization of substrates or chips 210, 220, adhesive media 204 on a plastic basis have mostly been used so far. Mechanical stability can also be achieved using these wire bonds or additional wire bonds.

As shown in FIG. 13a, a superconducting connection between two superconducting metals (bod pads) 212, 222 on different chips 210, 220, (e.g. niobium to niobium or another superconducting metal such as Ta) is provided via conventional wire bonds 202. Further, an adhesive connection 204 (adhesive bond) may be provided between chip 210 and chip 220 for mechanical attachment.

FIG. 13b shows a further conventional device 201 with another connection option of e.g. the structure of FIG. 13a by e.g. cold reflow to another bond partner A(n) 230.

As shown in FIG. 13b, a connection between two bond partners 210, 220 on e.g. different chips (e.g. A(2) 220 with A(1) 210, for n=3 and i=1) with superconducting metal pads 212, 222 (e.g. niobium to niobium or another superconducting metal such as Ta) is provided via conventional wire bonds 202. The connection layer 204 between the bond partners A(n−1)/A(1) is stabilized e.g. with or without an adhesive connection between bond partner 220 A(n−1) and bond partner 210 A(1) for mechanical attachment. Optionally, in the case of several bond partners 210, 220, 230, the lowest connection layer 206 between bond partners 220 and 230 “A(n)/A(n−1)” is often connected, e.g. in an electrically conductive way, by a reflow soldering process or cold reflow.

However, there a several problems with wire bonds. Wire bonds may come loose. Wire bonds prevent or complicate the 3D setup, which is essential for chiplet modules or 3D stacking, among other things.

Further, there a several problems with flip-chip and other established connection methods. Precisely defined spacing is not possible via the connection with In bumps on a planar substrate. Plane parallelism of the connected chips is not guaranteed. Specific angle dependency of the connected chips is not guaranteed. Exact distance between the connected chips is not guaranteed. Exact distance between the connected chips cannot be defined.

The wiring of a large number of qubits poses a problem for superconducting quantum devices, for example. Crossings of conductor paths, capacitive couplings, superconducting galvanic connections and the three-dimensional (3D) structure with a corresponding contacting between the chips are decisive challenges. It is therefore necessary to guarantee (as far as possible) precise distance control between the metal paths of two or more stacked chips. Further, homogeneity should be ensured across the chip and from chip to chip.

Therefore, it is an objective of the present disclosure to provide an improved electrical and superconductive connection concept for stacked substrates (e.g. stacked chips) and an improved method for fabrication such an improved connection concept, e.g. for superconducting quantum devices.

### SUMMARY

This summary and the following detailed description should be interpreted as complementary parts of an integrated disclosure, which parts may include redundant subject matter and/or supplemental subject matter. An omission in either section does not indicate priority or relative importance of any element described in the integrated application. Differences between the sections may include supplemental disclosures of alternative embodiments, additional details, or alternative descriptions of identical embodiments using different terminology, as should be apparent from the respective disclosures.

According to an embodiment of the present disclosure, a method for fabricating a substrate structure, has —providing a stack structure comprising a first substrate, a plastically deformable superconductor (superconductive material) layer (pad or layer pad), and a second substrate, wherein the first substrate has a main surface with a topographic structure and the second substrate has a main surface facing the main surface of the first substrate, wherein the main surface of the first substrate comprises a structured superconductor metallization and the main surface of the second substrate comprises a structured superconductor metallization, wherein the plastically deformable superconductor layer extends between the structured superconductor metallization of the first substrate and the structured superconductor metallization of the second substrate, and —exerting (mechanical) pressure to the first and second substrate for compressing the plastically deformable superconductor layer between the structured superconductor metallizations of the first and second substrates in order to form a mechanical and electrical superconductor connection between the structured superconductor metallizations of the first and second substrates.

According to an embodiment of the present disclosure, a substrate structure has —a stack structure comprising a first substrate, a plastically deformable superconductor layer, and a second substrate, wherein the first substrate has a main surface with a topographic structure and the second substrate has a main surface facing the main surface of the first substrate, wherein the main surface of the first substrate comprises a structured superconductor metallization and the main surface of the second substrate comprises a structured superconductor metallization, and —a compressed plastically deformable superconductor layer extending between the structured superconductor metallizations of the first and second substrates in order to provide a mechanical and electrical superconductor connection between the structured superconductor metallizations of the first and second substrates.

Embodiments of the present invention are based on the finding that, as a solution to the above indicated technical problems, the mechanical and electrical (and superconductive) connection of substrates or chips (e.g., a first and second substrate or chip for a superconducting quantum device) may be realized using a mechanically (plastically) deformable superconducting layer or bonding pad (e.g., plastically deformable superconductor layer), e.g. comprising or consisting of indium (In). Indium becomes superconductive below a transition temperature of 3.41 K (Kelvin). Indium (e.g. in form of an indium material pad) may be located on one or both connection partners (e.g., formed using a lithographic process, e.g., on the first substrate, the second substrate, or a portion thereof on the first substrate and a further portion thereof on the second substrate). At least one of the two connection partners (e.g., first and second substrate) has a single-step (two-step) or multi-step (multi-level) topographical structure (cf. FIGS. 3a-d, 4a-d, 5, 6, 7a-b). The deformable superconducting layer located on at least one of the two connection partners before the bonding process may be superconductively connected to other, e.g. superconducting, components (e.g., structured superconductor metallizations or contact areas) on the first and second substrate by mechanical pressing, e.g., exerting pressure for compressing the plastically deformable superconductor layer (bonding layer or bonding pad) using e.g. the flip-chip process.

According to embodiments of the present invention, plastically deformable (formable or malleable) materials, that also exhibit electrically conductive and superconducting properties, may comprise or consist of electrically conductive and superconducting metals or metal alloys (composed of a combination of several metals or superconducting metals) that intrinsically exhibit this plastic deformability, such as indium, etc. According to embodiments of the present invention, plastically deformable (electrically conductive and superconducting) materials or substances may also comprise or consist of electrically conductive and superconducting soldering agents or solder pastes.

According to embodiments of the present invention, plastically deformable (electrically conductive and superconducting) materials or substances may also comprise or consist of electrically conductive and superconducting soldering agents or solder pastes.

According to embodiments of the present invention, further plastically deformable (electrically conductive and superconducting) materials or substances may also contain or consist of electrical and superconducting pastes or sinter pastes (sintering pastes).

According to embodiments of the present invention, the fabricated substrate structure may be used for/in an ion trap, a quantum computing device (or quantum computer), a superconducting quantum interference device, or other devices which use superconducting connections.

### BRIEF DESCRIPTION OF THE DRAWINGS

In the following, embodiments of the present disclosure are described in more detail while making reference to the accompanying drawings, in which

FIG. 1 shows an exemplary schematic flow chart of a fabrication method according to an embodiment of the present disclosure;

FIG. 2 shows a schematic process flow for fabricating a substrate structure according to an embodiment of the present disclosure;

FIGS. 3a-d show different schematic cross sectional views of a superconducting chip-to-chip (substrate-to-substrate) connection of a (substrate structure having a) topographically structured substrate and a planar substrate according to an embodiment of the present disclosure;

FIGS. 4a-d show different schematic cross sectional views of a superconducting chip-to-chip connection of a (substrate structure having a) two topographically structured substrates according to a further embodiment of the present disclosure;

FIG. 5 shows a schematic cross sectional view of a substrate structure having a two topographically structured substrates in a connected state according to a further embodiment of the present disclosure;

FIG. 6 shows a schematic cross sectional view of a substrate structure having a two topographically structured substrates in a connected state according to a further embodiment of the present disclosure;

FIGS. 7a-b show schematic cross sectional views of a through-vias of a substrate according to a further embodiment of the present disclosure;

FIGS. 8a-e show different schematic cross sectional views of connections options of the substrate structure according to a further embodiment of the present disclosure;

FIGS. 9-11 show further different schematic cross sectional views of connections options of the substrate structure according to further embodiments of the present disclosure; and

FIG. 12 shows a schematic cross sectional view of a substrate structure having a two substrates in a connected state according to a further embodiment of the present disclosure;

FIGS. 13a-b show schematic cross sectional views of conventionally connected devices (chips).

Before discussing the present embodiments in further detail using the drawings, it is pointed out that in the figures and the specification identical elements or method steps and elements or method steps having the same functionality and/or the same technical or physical effect are usually provided with the same reference numbers or are identified with the same name, so that the description of these elements or method steps and of the functionality thereof as illustrated in the different embodiments are mutually exchangeable or may be applied to one another in the different embodiments.

### DETAILED DESCRIPTION

In the following description, embodiments are discussed in detail, however, it should be appreciated that the embodiments provide many applicable concepts that can be embodied in a wide variety of the field of devices having a substrate structure with stacked chips or substrates, e.g., superconducting quantum devices having of a large number of wired qubits. The specific embodiments discussed are merely illustrative of specific ways to implement and use the present concept, and do not limit the scope of the embodiments. In the following description of embodiments, the same or similar elements (method steps) or elements that have the same functionality are provided with the same reference sign or are identified with the same name, and a repeated description of elements provided with the same reference number or being identified with the same name is typically omitted. In the following description, a plurality of details is set forth to provide a more thorough explanation of embodiments of the disclosure.

However, it will be apparent to one skilled in the art that other embodiments may be practiced without these specific details. In other instances, well-known structures and devices are shown in block diagram form rather than in detail in order to avoid obscuring examples described herein. In addition, features of the different embodiments described herein may be combined with each other, unless specifically noted otherwise.

It is understood that when an element is referred to as being “connected” or “coupled” to another element, it may be directly connected or coupled to the other element, or intermediate elements may be present. Conversely, when an element is referred to as being “directly” connected to another element, “connected” or “coupled,” there are no intermediate elements. Other terms used to describe the relationship between elements should be construed in a similar fashion (e.g., “between” versus “directly between”, “adjacent” versus “directly adjacent”, and “on” versus “directly on”, etc.).

For facilitating the description and the understanding of the different embodiments, the figures comprise a Cartesian coordinate system x, y, z, wherein the x-y-plane corresponds, i.e., is parallel, to a first main surface region of a substrate, chip or PCB (=a reference plane=x-y-plane), wherein the direction vertically up with respect to the reference plane (x-y-plane) corresponds to the “+z” direction, and wherein the direction vertically down with respect to the reference plane (x-y-plane) corresponds to the “−z” direction. In the following description, the term “lateral” means a direction parallel to the x- and/or y-direction, i.e., parallel to the x-y-plane, wherein the term “vertical” means a direction parallel to the z-direction.

In the following description, a thickness of an element usually indicates a vertical dimension of such an element. In the figures, the different elements are not necessarily drawn to scale. Thus, the illustrated dimensions of the different elements may not be necessarily drawn to scale.

In the description of the embodiments, terms and text passages placed in brackets next to a described element or function are to be understood as further explanations, alternative designations, exemplary configurations, exemplary additions and/or exemplary alternatives of the described element or function.

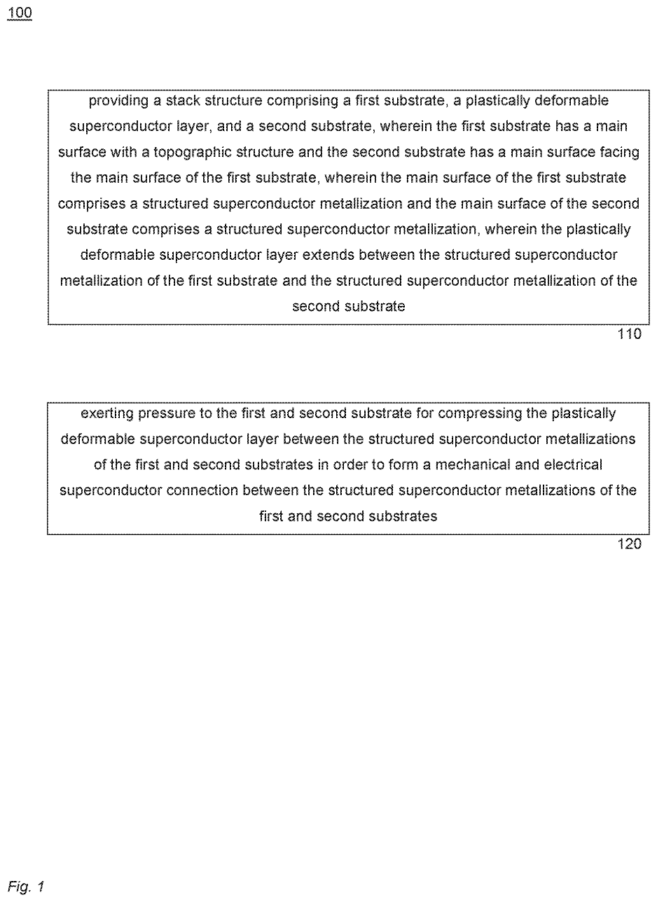

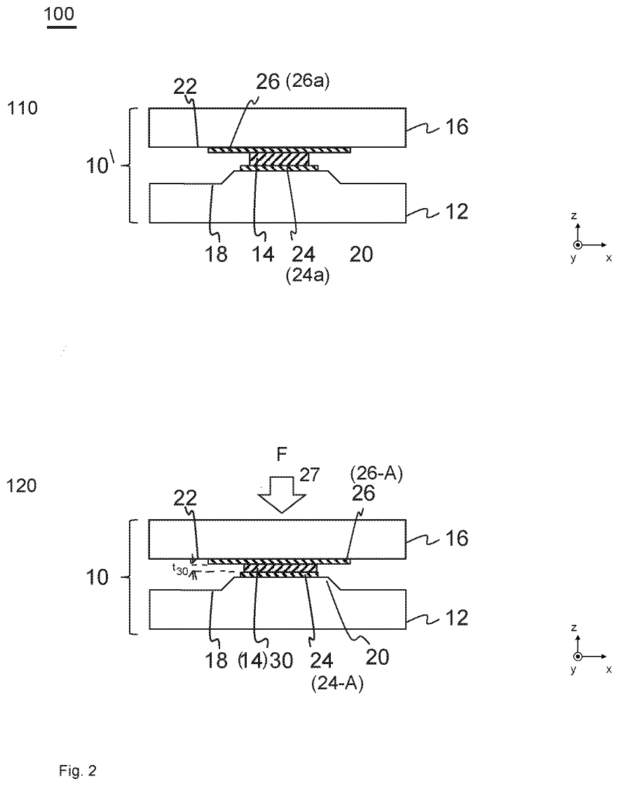

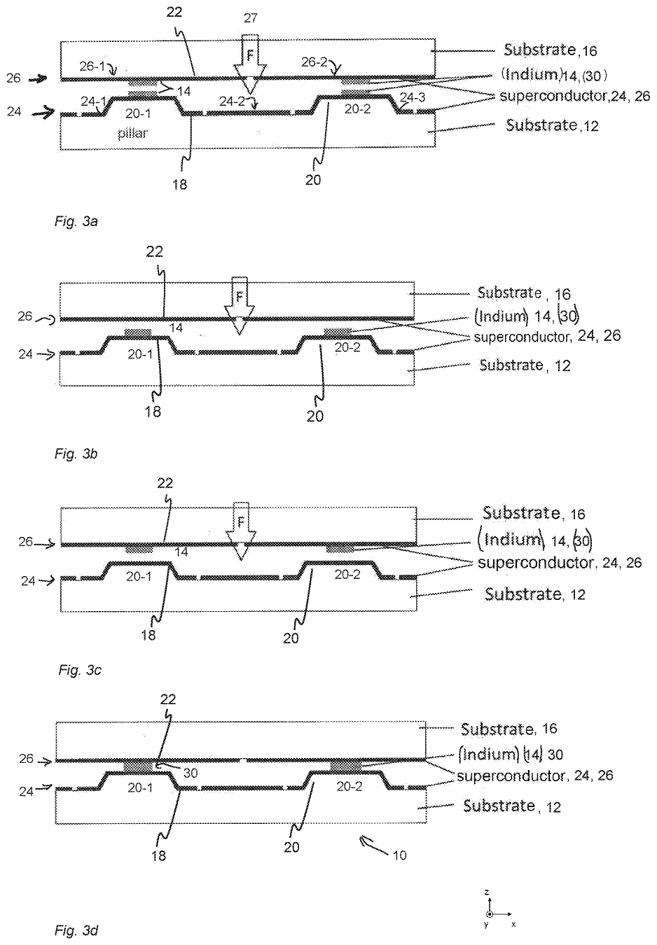

FIG. 1 shows an exemplary schematic flow chart of a fabrication method 100 according to an embodiment of the present disclosure. FIG. 2 shows a schematic process flow of the fabrication method 100 for fabricating a substrate structure according to an embodiment of the present disclosure. The following evaluations in connections with FIGS. 1 and 2 equally applicable to the further embodiments as described in connection with FIGS. 3a-b to 12.

According to an embodiment (see FIGS. 1 and 2, for example), the method 100 for fabricating a substrate structure 10, comprises a step 110 of providing a stack structure 10′ (see FIG. 2) comprising a first substrate 12 (e.g., a semiconductor or silicon substrate), a plastically deformable superconductor (superconductive material) layer (pad or layer pad) 14, e.g., comprising or consisting of indium), and a second substrate 16 (e.g., a semiconductor or silicon substrate), wherein the first substrate 12 has a main surface (region) 18 with a topographic structure 20 and the second substrate 16 has a main surface (region) 22 facing the main surface 18 of the first substrate 12. The main surface 18 (e.g., at least a portion of the topographic structure 20) of the first substrate 12 comprises a structured superconductor metallization (contact area) 24, e.g., comprising one (material) or more materials (a material compound) of Al (aluminum), Nb (niobium), Ta (tantalum), TiN (titanium nitride), and the main surface 22 of the second substrate 16 comprises a structured superconductor metallization (contact area) 26, e.g., comprising one or more of Al, Nb, Ta, TiN. The plastically deformable superconductor layer 14 is arranged (extends) between the structured superconductor metallization 24 of the first substrate 12 and the structured superconductor metallization 26 of the second substrate 16.

According to an embodiment, the structured superconductor metallization (contact area) 24 of the first substrate 12 and/or the structured superconductor metallization (contact area) 26 of the second substrate 16 may comprise a layer sequence or layer stack having a plurality of different layers, wherein each of the layers comprise or consist of an electrically conductive and superconducting material (e.g. electrically conductive and superconducting metal).

According to an embodiment, the structured superconductor metallization (contact area) 24 or 26 or (at least) one of the structured superconductor metallizations 24-1, . . . of the first or second substrate 12 or 16 may form a ground metallization (ground contact area).

The method 100 further comprises a step 120 of exerting (mechanical) pressure 27 (e.g., exerting a force F) to at least one of the first and the second substrate 12, 16 (see FIGS. 1 and 2, for example) for compressing (e.g., applying a force to compress, e.g., to one or both of the first and second substrate 12, 16, e.g., cold-welding) the plastically deformable superconductor layer 14 (e.g., by moving the first and second substrate towards each other) between the structured superconductor metallizations 24, 26 of the first and second substrates 12, 16 in order to form a mechanical and electrical superconductor connection 30 between the structured superconductor metallizations 24, 26 of the first and second substrates 12, 16.

Consequently, the “compressed” and plastically deformed superconductor layer 14 (30) forms a mechanical and electrical superconductor connection 30 between the structured superconductor metallizations 24, 26 of the first and second substrates 12, 16.

According to the present disclosure, the (compressed) plastically deformable superconductor (superconductive material) layer (bonding material pad or layer pad) 14 forms a mechanical connection based on its plastically deformable material characteristic, as plastically deformable materials undergo permanent, irreversible shape changes when the applied stress (mechanical force) exceeds their yield strength, without breaking or cracking. The material 14 does not return to its original shape or size after the load is removed. The plastic deformation begins only after the material passes its elastic limit, known as the yield point.

Moreover, the (compressed) plastically deformable superconductor (superconductive material) layer (bonding material pad or layer pad) 14 forms an electrical conductivity above its (material dependent) superconductivity transition temperature and provides super-conductivity (superconductive characteristic) below its superconductivity transition temperature.

Thus, in the context of this description, a plastically deformable material is defined as a material that permanently, non-reversibly changes its shape or size, when it is subjected to force (e.g. by applying pressure, stress or compressive force) exceeding its yield strength without breaking or tearing. This property is referred to as plasticity (plastic deformability), whereby the deformation remains even after the external force has been removed. Thus, plastic deformability is the capacity of a solid material to undergo permanent, irreversible changes in shape when subjected to applied forces exceeding its yield strength.

According to embodiments of the present invention, plastically deformable (formable or malleable) materials, that also exhibit electrically conductive and superconducting properties, may comprise or consist of electrically conductive and superconducting metals or metal alloys (composed of a combination of several metals or superconducting metals) that intrinsically exhibit this plastic deformability, such as indium, etc. According to embodiments of the present invention, plastically deformable (electrically conductive and superconducting) materials or substances may also comprise or consist of electrically conductive and superconducting soldering agents or solder pastes. According to embodiments of the present invention, plastically deformable (electrically conductive and superconducting) materials or substances may also comprise or consist of electrically conductive and superconducting soldering agents or solder pastes. According to embodiments of the present invention, further plastically deformable (electrically conductive and superconducting) materials or substances may also contain or consist of electrical and superconducting pastes, e.g. sinter pastes, in order to electrically (and superconductively) and mechanically connect the opposing contact areas on opposing substrates (chips, etc.). Electrically conductive pastes can, for example, be subjected to a curing process to achieve their conductivity. Curing can be carried out, for example, by heat application (thermal curing) or at room temperature (air drying).

The substrates 12, 16 may typically comprise or consist of materials, such as a semiconductor (silicon, poly-Si), glass, quartz, corundum, diamond or ceramic material.

According to the present disclosure, the first substrate 12 and/or the second substrate 16 may have a planar shape, e.g., generally planar on a larger scale but with further structures such as the topographic structure on a smaller scale. The first substrate 12 and/or the second substrate 16 may be formed from a portion of a wafer (e.g., a wafer die). The first and/or second substrate 12, 16 may comprise or consist of silicon, e.g., monocrystalline silicon. The first and/or substrate 12, 16 may comprise an insulation (e.g. oxide) layer (e.g., silicon oxide), which may form at least a portion of the respective main surface 18, 22. The first and/or second substrate 12, 16 may comprise or consist of other substrate material that as a III-V-semiconductor material (and optionally a corresponding oxide).

In the present disclosure, the term “lateral” may relate to directions along a planar (e.g., horizontal) extension of the first and/or second substrate. The term “vertical” may relate to a direction perpendicular to the lateral directions. For example, a substrate 12, 16 may have a planar, plate like shape with two longer edges (e.g., framing the main surface) extending along lateral directions (e.g., x-direction and y-direction) and a shorter wall thickness direction (e.g., z-direction) that is perpendicular to the two longer edges.

The plastically deformable superconductor layer (layer pad) 14 may comprise or may consist of metal, e.g., a single element (e.g., Indium, e.g., having more than 99% of one element) or an alloy (e.g., having a compound of two, three or more metals). The plastically deformable superconductor layer 14 (e.g., the single element or the alloy) may comprise a doping, e.g., with a concentration of less than 1%, less than 0.1%, or less than 0.01%. Plastic deformability may comprise permanent deformation and/or retaining (e.g., entirely or essentially entirely, e.g., with less than 5% elastic deformation or less than 5% reversal of an initial deformation) a shape after a shaping force (e.g., compressing force) is no longer applied. The plastically deformable superconductor layer 14 may exhibit plastic deformability for temperatures above 0° C., above −50° C., above −100° C., or above OK.

The plastically deformable superconductor layer 14 may have a homogenous composition (e.g., and optionally have an oxide layer). The plastically deformable superconductor layer 14 may comprise a material composition, e.g., having a single element such as indium or an alloy, that extends from the first substrate 12 to the second substrate 16. In other words, the plastically deformable superconductor layer 14 may comprise a same composition from the structured superconductor metallization 24 of the first substrate 12 (e.g., a mechanical contact thereto) to the structured superconductor metallization 26 of the second substrate 16 (e.g., a mechanical contact thereto). Alternatively, the plastically deformable superconductor layer 14 may have a layered structure.

For example, the plastically deformable superconductor layer 14 may comprise a contacting layer 14a that is in mechanical contact with the structured superconductor metallization 24 of the first substrate 12, a further contacting layer 14b that is mechanical contact with the structured superconductor metallization 26 of the second substrate 16 and an intermediate layer 14c between the two contacting layers 14a, 14b. The plastically deformable superconductor layer 14 may have a column shape, e.g., with a vertical extension direction, e.g., with a constant cross section. The plastically deformable superconductor layer 14 may have a vertical extension (e.g., height) that is smaller than its lateral extension in one (e.g., x-direction or y-direction), two (x-direction and y-direction) or all (e.g., any combination of x- and y-direction) lateral directions.

The plastically deformable superconductor layer 14 may not necessarily exhibit a superconducting state (e.g., with vanishing electrical resistance) for one or more steps of the method disclosed herein, but may be switchable to a superconducting state, e.g., by cooling down, e.g., after manufacturing of the substrate structure 10 is completed. For example, the plastically deformable superconductor layer 14 may consist of or comprise Indium, wherein one or more (or all) steps of the method 100 for fabricating a substrate structure 10 may be carried out at a temperature, in which indium is not in a superconducting state. However, indium can switch to a superconducting state (or become superconducting) by cooling below its critical temperature (transition temperature), with TC(IN)=3.41 K.

In the present disclosure, the term “superconductor” and “superconducting” may be interchangeable in meaning that the material is capable of switching to a superconducting state without necessarily having to be in the superconducting state during manufacturing. For example, the plastically deformable superconductor layer 14 may be referred to as plastically deformable superconducting layer and the structured superconductor metallization may be referred to as structured superconducting metallization. However, in either case, the term “superconducting” references the ability to switch to a superconducting state, but does not necessarily entail a superconducting state during manufacturing.

The plastically deformable superconductor layer 14 may be in mechanical contact with the first and second substrate 12, 16 only via the structured superconductor metallizations 24, 26 of the first and second substrates 12, 16. For example, the plastically deformable superconductor layer 14 may not be in mechanical contact with a portion of the main surfaces 18, 22 of the first and/or second substrate which are not covered by the structured superconductor metallizations 24, 26. Similarly, the mechanical and electrical superconductor connections 30 may be in mechanical contact with the first and second substrate 12, 16 only via the structured superconductor metallizations 24, 26 of the first and second substrates 12, 16. As the compression of the plastically deformable superconductor layer 14 may result in a lateral expansion thereof, exerting the pressure (step 120) to the first and second substrate 12, 16 may be controlled so as to avoid plastically deformable superconductor layer 14 mechanically contacting any component of the first and second substrate 12, 16 other than the structured superconductor metallizations 24, 26, e.g., by limiting the exerted pressure to a maximum threshold, and/or, by limiting a material amount and/or height of the plastically deformable superconductor layer 14. Furthermore, the topographic structures 20 may be formed such so as to avoid such contacting, e.g., by forming a recess with enough volume to receive the compressed plastically deformable superconductor layer 14.

Each substrate 12, 16 may comprise two or more structured superconductor metallizations 24, 26. The two or more structured superconductor metallizations 24, 26 may be electrically not in (direct) contact with each other. Thus, the substrate 12 may comprise two or more structured superconductor metallizations 24, which may be electrically not in (direct) contact with each other, and the substrate 16 may comprise two or more structured superconductor metallizations 26, which may be electrically not in (direct) contact with each other. However, one or more of the structured superconductor metallizations 24, 26 may be (indirectly) electrically connected to each other via another element, e.g., the plastically deformable superconductor layer 14 (e.g., forming a serial connection of a structured superconductor metallization, a plastically deformable superconductor layer, and another structured superconductor metallization).

The layer stack 10′ may comprise more than one plastically deformable superconductor layer 14. The one or more plastically deformable superconductor layers 14 may not electrically contact each other (directly). However, two or more plastically deformable superconductor layers 14 may be indirectly electrically connected to each other via another element, e.g., a structured superconductor metallization 24, 26 (e.g., forming a serial connection of a plastically deformable superconductor layer, a structured superconductor metallization, and another plastically deformable superconductor layer).

The topographic structure 20 of at least one of the substrates 12, 16 may define a three dimensional surface, e.g., wherein the surface cannot all be arranged within a single two-dimensional plane. The topographic structure 20 may comprise one or more localized elevations and/or may comprise one or more localized recesses.

The structured superconductor metallization 24, 26 of the first and/or second substrate 12, 16 may cover a portion of the respective main surface 18, 22 and therefore adapt (reshape) a surface shape of the covered portion. For example, the structured superconductor metallization 24, 26 may have a flat shape on a flat portion of the main surface, a curved shape at a curved portion of the main surface (e.g., at an elevation or recess), etc. A portion of, all of or none of the structured superconductor metallizations 24, 26 of the first and/or second substrate 12, 16 may be arranged on top of (e.g., cover) the respective topographic structure 20. For example, the topographic structure 20 of the first substrate 12 may comprise elevations, wherein the structured superconductor metallization 24 may be arranged on top of (some or all of) the elevation(s) 20. In a different example, the structured superconductor metallization 24 may extend from a region without the topographic structure onto the topographic structure 20.

The substrate structure 10 may comprise one or more mechanical and electrical superconductor connections 30. The first and second substrates 12, 16 may be only mechanically connected by the one or more mechanical and electrical superconductor connections 30, i.e. may comprise no other mechanical connections. Optionally, the first and second substrates 12, 16 may abut against each other at other surfaces at which no mechanical connection is realized, e.g., a structured superconductor metallization of the first substrate 12 may abut against a structured superconductor metallization of the second substrate 16, but no mechanical connection is provided between the abutting structured superconductor metallizations. Alternatively, the substrate structure 10 may comprise one or more further mechanical connections between the first and second substrate 12, 16, which are different or spaced from the one or more mechanical and electrical superconductor connections 30. The one or more mechanical and electrical superconductor connections may be configured to prevent translation and/or rotation of the first substrate 12 relative to the second substrate 16.

The plastically deformable superconductor layer 14 may be in mechanical contact with the structured superconductor metallizations 24, 26 of the first and second substrates 12, 16 before executing the step 120 of exerting pressure to the first and second substrate 12, 16. In other words, the plastically deformable superconductor layer 14 may be arranged (extend) from the structured superconductor metallization 24 of the first substrate 12 to the structured superconductor metallization 26 of the second substrate 16.

The step 120 of exerting pressure to the first and second substrate 12, 16 may comprise arranging one of the first and second substrates 12, 16 at a fixed position and moving the other one of the first and second substrate 12, 16 towards the substrate at the fixed position. Alternatively, both, the first and second substrates 12, 16 may simultaneously be moved towards each other. The step of exerting pressure can be performed manually by a user, e.g., by placing one of the first and second substrate 12, 16 on a flat surface (e.g., table surface) and applying pressure by hand onto the other one of the first and second substrate 12, 16, e.g., compressing the stack structure by hand. Alternatively or additionally, the step 120 of exerting pressure may comprise placing the stack structure 10′ between two pressure plates and moving at least of the two pressure plates or both pressure plates towards each other by the use of one or more actuators.

The step 120 of exerting pressure 27 to the first and second substrate 12, 16 for compressing the plastically deformable superconductor layer 14 may be referred to (or may realize) a (mechanical) bonding (e.g., attaching) of the second substrate 16 to the first substrate 12, e.g., using the plastically deformable superconductor layer 14 as bonding material. The step 120 of exerting pressure 27 may be performed without one or more of applying heat, applying vibrations, and applying an electric current.

A (e.g., vertical) thickness t30 of the compressed plastically deformable superconductor layer 30 may be controlled by the exerted pressure 27, e.g., exerted force. A target thickness of the compressed plastically deformable superconductor layer 14 may be controlled by one or more signals representative one or more of the exerted pressure 27, a temperature T, a position of the first and/or second substrate 12, 16, and an image captured of the plastically deformable superconductor layer 14.

Compressing the plastically deformable superconductor layer 14 may comprise a flattening, clamping, squeezing, or squashing of the plastically deformable superconductor layer 14. In compressing the plastically deformable superconductor layer 14, a thickness of the plastically deformable superconductor layer 14 (e.g., in a direction from the first to the second substrate, e.g., in vertical direction) may be reduced by or more than 2%, 5%, 10%, more than 25%, more than 50% or more than 75%, when compared to an uncompressed state of the plastically deformable superconductor layer 14. The compression of the plastically deformable superconductor layer 14 may result in a cold welding between the plastically deformable superconductor layer 14 and the structured superconductor metallizations 24, 26 of the first and second substrates 12, 16. Compressing the plastically deformable superconductor layer 14 may result in material of the plastically deformable superconductor layer 14 being forced into small cracks and recesses of the structured superconductor metallizations 24, 26, causing a mechanical connection.

The mechanical and electrical superconductor connection 30 between the structured superconductor metallizations 24, 26 of the first and second substrates 12, 16 may be switchable to a superconducting state, e.g., by cooling below the transition temperature TC of the material of the plastically deformable superconductor layer 14 and of the material of the structured superconductor metallizations 24, 26, respectively, wherein a resistance between the structured superconductor metallizations 24, 26 of the first and second substrates 12, 16 vanishes (or becomes zero). As a result, an electrical current can flow between the structured superconductor metallizations 24, 26 (through the mechanical and electrical superconductor connection 30) without electrical resistance. The mechanical and electrical superconductor connection 30 may be formed only of the material of the plastically deformable superconductor layer 14, e.g., without additional materials between plastically deformable superconductor layer 14 and one or both of the structured superconductor metallizations 24, 26. For example, the plastically deformable superconductor layer 14 may be formed by indium, wherein the mechanical and electrical superconductor connection 30 is formed by said indium (e.g., and potentially oxide due to forming of an oxide layer), but in a compressed state (e.g., wherein portions of the indium 14 is compressed and, for example, is pressed into cracks and recesses of the structure superconductor metallization 24, 26). The mechanical and electrical superconductor connection 30 may comprise material of the structured superconductor metallizations 24, 26, e.g., due to diffusion and/or pressing of said material into cracks and recesses of the plastically deformable superconductor layer 14.

The mechanical and electrical superconductor connection 30 may have a critical temperature TC, under which the mechanical and electrical superconductor connection 30 switches to a superconducting state. The critical temperature TC may be a lower one of a critical temperatures of the plastically deformable superconductor layer 14 and the structured superconductor metallizations 24, 26. The method 100 may comprise a step 130 of switching the mechanical and electrical superconductor connection 30 to a superconducting state, e.g., for testing and/or operation of the substrate structure. The method 10 may comprise using the substrate structure 10 in an ion trap, a quantum computing device (or quantum computer), a superconducting quantum interference device, or other devices which use superconducting connections.

The step 110 of providing the stack structure 10′ may comprise orienting the main surface 22 of the second substrate 16 to face the main surface 18 of the first substrate 12, e.g., by flipping the first or second substrate 12, 16 by 180°, e.g., after the first and second substrate 12, 16 have been fabricated facing the same way. The step 110 of providing the stack structure 10′ may further comprise mechanically contacting the first and second substrate 12, 16 in such a way that the plastically deformable superconductor layer 14 is arranged between the structured superconductor metallizations 24, 26 of the first and second substrates 12, 16. The step 110 of providing a stack structure 10′ may further comprise forming the plastically deformable superconductor layer 14 on a structured superconductor metallization 24, 26 of one of the first and second substrate 12, 16, and, for example, subsequently contacting the plastically deformable superconductor layer 14 with the structured superconductor metallization 24, 26 on which the plastically deformable superconductor layer 14 has not been formed. The step 110 of providing the stack structure 10′ may further comprise forming a portion of the plastically deformable superconductor layer 14 on a structured superconductor metallization 24 of the first substrate 14 and a further portion of the plastically deformable superconductor layer 14 on the second substrate 16, e.g., wherein the two portions of the plastically deformable superconductor layer 14 may be combined to form the plastically deformable superconductor layer 14, e.g., by mechanically contacting both portions (i.e. the portion and the further portion).

Depending on the respective plastically deformable material (metal, solder or paste, etc.), it may also be necessary to carry out the deformation process (the step of exerting force) at an elevated temperature of the plastically deformable superconductor layer 14 in order to achieve the plastic deformation of the electrically conductive and superconducting layer material 14 under the influence of force and elevated temperature. By increasing the temperature of the plastically deformable (electrically conductive and superconducting) material, for example, the deformability during the deformation process can be increased.

For example, when using electrically conductive and superconducting solders or solder pastes for the plastically deformable superconductor layer 14, in addition to applying force to at least one of the two substrates involved, an elevated temperature can also be applied or exerted for the deformation process. The elevated temperature can be applied or exerted at least in the area of the plastically deformable superconductor layer 14, where the superconducting connection between the two substrates is to be provided. This allows the plastically deformable superconducting layer 14 between the structured superconducting metallizations of the first and second substrates 12, 16 to be heated in order to reduce the viscosity of the material of the plastically deformable superconducting layer 14 and to increase its deformability, respectively. Then, in the step 120 of exerting force (applying pressure) to the first and second substrates to compress the plastically deformable superconducting layer 14, the mechanical and electrical superconducting connection between the structured superconducting metallizations of the first and second substrates can be formed.

Thus, the method 100 may further comprise a step 150 of heating the plastically deformable superconducting layer 14 between the structured superconducting metallizations 24, 26 of the first and second substrate 12, 16 before and/or during the step 120 of exerting pressure the first and second substrates 12, 16.

Thus, the heating (increase of temperature) 150 of the plastically deformable superconducting layer 14 can be used to reduce the viscosity and/or to increase the deformability of the material of the plastically deformable superconducting layer 14 in order to form the mechanical and electrical superconducting connection 30 between the structured superconducting metallizations 24, 26 of the first and second substrates 12, 16 during the step 120 of applying pressure to the first and second substrates 12, 16 to compress the heated, plastically deformable superconducting layer 14.

Further, the heating (increase of temperature) 150 of the plastically deformable superconducting layer 14 can be maintained or conducted after (completion of) the step 120 of exerting pressure the first and second substrates 12, 16, e.g. for a follow-up time period, to further enhance the mechanical and/or electrical connection of the plastically deformable superconducting layer 14 with the structured superconducting metallizations 24, 26.

Furthermore, when using an electrically conductive and superconductive paste, e.g. sinter paste, for the plastically deformable superconductor layer 14, for example, after the step 120 of exerting (applying) force to the first and second substrates 12, 16 to compress the plastically deformable paste 14, a curing process (optional step 160) of the compressed, electrically conductive and superconductive paste can also be carried out. This curing step (solidification or hardening step) can also be carried out at an elevated temperature, for example, in order to accelerate the curing of the electrically conductive and superconductive paste. Alternatively, air drying can also be carried out simply (without increasing the temperature) at room temperature until, for example, the solvent present in the paste has escaped (evaporated) and the plastically deformed paste has cured, i.e., has reached its plastically deformed final state.

An electrical and superconducting connection by sintering an electrically conductive and superconductive paste (sinter paste) provides an assembly and connection technology, in which components (e.g., the substrates or chips 12, 16) are firmly and electrically conductively connected by pressure and heat below the melting temperature of the sinter material 14.

Thus, the method 100 may further comprise a step 160 of curing the (compressed) plastically deformed superconducting layer 14 between the structured superconducting metallizations 24, 26 of the first and second substrates 12, 16 after the step 120 of exerting pressure the first and second substrate(s) 12, 16, wherein the plastically deformable superconductor layer 14 comprises or consists of an electrically conductive and superconductive paste. The curing allows to evaporate the solvent from the superconducting paste 14, for example, at an elevated temperature to accelerate the curing process 160.

According to an embodiment of the present invention, a reliably superconducting bond (=the mechanical and electrical superconductor connection 30) can be achieved based on the following material and implementation options for the plastically deformable superconductor layer 14:
Pure superconducting metals (Al, Pb, In, Sn, Nb, Ta, V, Ga . . . )
or their superconducting alloys as
   Wire/tape/compression bond
   or solder/bump/sintered metal connection.

The following tables list the selected materials that can be used in the acceptable or limiting temperature range in the manufacture of the inventive substrate structure 10.

Table 1 shows an exemplary material list of ductile, plastically deformable superconducting metals and associated material characteristics for the plastically deformable superconductor layer 14.

TABLE 1
1. Ductile, plastically deformable superconducting metals

| | | Melting temp. | | |
|---|---|---|---|---|
| Material | T_{c} [K] | [° C.] | Ductility/ | Typical connection/ |
| 14 | (approx.) | (approx.) | Property | bonding method |
| Indium | ~3.4 | 157 | Extremely soft, | Bumps, wafer bonding, |
| (In) | | | very good plastic | compression bonding, |
| | | | deformability | sintered In paste |
| Tin | ~3.7 | 23 | Soft, highly | Solder bump, solder wire, |
| (Sn) | | | malleable | sintered Sn paste |
| Gallium | ~1.1 | 29.8 | Liquid at | Exotic contacts, filler |
| (Ga) | | | RT/very soft | metal, difficult to |
| | | | | handle in practice |

Table 2 shows an exemplary list of solderable superconducting materials (solders, bumps).

TABLE 2
2. Solderable superconducting materials (solders, bumps)

| | | Solidus/ | Typical | |
|---|---|---|---|---|
| | | liquidus | reflow/ | |
| Material/alloy | T_{c} [K] | [° C.] | soldering | |
| 14 | (typical) | (approx.) | temp. [° C.] | Comments |
| Pure In | ~3.4 | 157 | ~150-190 | Standard for low-temperature |
| | | | | bumps and wafer bonding; |
| | | | | very soft, very good wetting |
| | | | | properties |
| Pure Sn | ~3.7 | 232 | ~230-260 | Lead-free solder, bumps; |
| | | | | superconducting <3.7 K |
| Pb—Sn solders (e.g., | roughly 4-7 | ~183-190 | ~190-230 | Classic flip chip solders; |
| 63Sn/37Pb, 60Sn/40Pb) | | | | superconducting in the range |
| | | | | of several Kelvin |
| In—Sn solders (e.g., | ~3-5 | ~118 | ~120-160 | Low-temperature |
| eutectic ~52In/48Sn) | | | | solder/bump, very suitable for |
| | | | | cryogenic applications |
| Pb—In solders (various | ~4-7 | ~150-220 | ~160-230 | Soft solders for low |
| compositions) | | | | temperatures; exactT_{c} |
| | | | | depending on composition |
| Indium-based multi- | Mostly 2-4 | ~80-200 | ~100-220 | Can be superconducting if a |
| component solders (e.g., | | | | continuous In/Sn metal |
| In—Ag, In—Sn—Ag, In—Sn—Bi) | | | | network is formed |

Table 3 shows an exemplary implementation of a superconducting sintered connection and its exemplary materials. Table 3 further shows the integrated collection with the variant for an intermediate layer metallization 24a, 26a (Si/Al/TiN/In or In—Sn, TiN superconducting).

TABLE 3
3. Example: “Superconducting sintered connection”
Substrate Si, Al metallization, superconducting TiN, In/In—Sn sintered material

| | Metallization/ | | Typical | | |
|---|---|---|---|---|---|
| | layer structure | Sinter/solder | sintering/ | | Conditions for |
| Substrate | (vertical) | material | reflow | Superconducting | superconducting |
| 12, 16 | 24, 24a-26, 26a | (example) 14 | range [° C.] | path/T_{c} | end state |
| Si 12, 16 | Si → structured Al | In paste or | In: ~150- | Current path: Al → | 1) Use TiN as the |
| | metallization 24a, | In—Sn paste, | 190; In—Sn | TiN (super- | superconducting |
| | 26a (islands/ | which be- | (eutectic | conducting, T_{c} ~3-5 | variant (suitable |
| | conductor tracks, | comes a | ~52In/48Sn): | K) → In/In—Sn | process window), |
| | not continuous) → | continuous | ~120-160 | (superconducting, T_{c} | 2) Al—TiN and |
| | continuous TiN | In/In—Sn metal | | ~3-5 K); effective T_{c} | TiN—In/In—Sn |
| | layer (set to | network | | of the entire con- | interfaces |
| | superconducting) | | | nection limited by the | should be as low in |
| | → sintered/melted | | | smallestT_{c} in the path | oxidation as |
| | In or In—Sn 24, 26 | | | → typically Al with | possible/highly |
| | | | | ~1.2 K | metallic, 3) |
| | | | | | sintered/melted |
| | | | | | In/In—Sn forms a |
| | | | | | continuous |
| | | | | | superconducting |
| | | | | | path between the Al |
| | | | | | structures |

According to an embodiment, the main surface 22 of the second substrate 16 comprises a topographic structure 28, e.g., having thereon at least a portion of the structured superconducting metallization 26 of the second substrate 16.

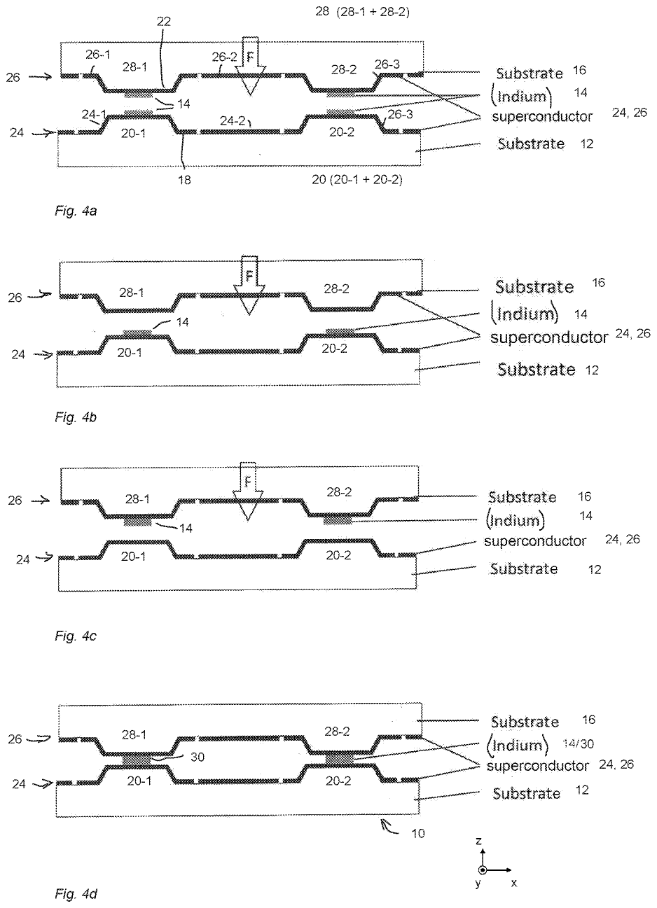

The topographic structure 28 of the second structure 16 (see, for example, FIGS. 4a-d, 5, 6) may have two or more elevations (pillars) 28-1, 28-2 that laterally coincide with two or more elevations (pillars) 20-1, 20-2 of the topographic structure 20 of the first substrate 12. The two or more elevations of the first and/or second substrate 12, 16 may have a flat (top) surface, e.g., wherein the two or more elevations of a respective substrate 12, 16 are arranged in a common plane, e.g., at the same (vertical) height. Elevations of the first substrate 12 that are arranged in a common plane may coincide with elevations of the second substrate 16 that are arranged in a common plane. As a result, the first and second substrate 12, 16 may abut against each other at the (opposing) elevations (see, for example FIGS. 4a-d), forming a cavity or empty space laterally between the elevations. One or more of such elevations (e.g., in common planes) may comprise structured superconductor metallizations 24, 26, e.g., with the plastically deformable superconductor layer 14. As a result, the first and second substrates may be electrically and mechanically connected at the elevations.

According to an embodiment, the plastically deformable superconductor layer 14 extends between two surfaces 24-A, 26-A of the structured superconductor metallizations 24, 26 of the first and second substrates 12, 16.

According to an embodiment, the two surfaces of the structured superconductor metallizations 24, 26 are parallel to each other, e.g., wherein compressing the plastically deformable superconductor layer 14 comprises applying a compressive force on the stack structure that is oriented perpendicular to the two parallel surfaces of the structured superconductor metallizations 24, 26.

Since the surfaces 24-A, 26-A are parallel (or plane parallel) to each other, a compression of the plastically deformable superconductor layer 14 may result in a more even lateral expansion. However, the surfaces 24-A, 26-A may be structured. For example, at least of the surfaces may be slanted in order to reduce the risk of plastically deformable superconductor layer 14 expanding into an undesired region (e.g., due to the risk of an electrical short and/or expansion into a space for different applications such as an ion trap). Furthermore, at least one of the surfaces may be structured (e.g., riffled) in order to reduce the risk of lateral sliding of the first and/or second substrate 12, 16.

According to an embodiment, a region of the structured superconductor metallization 24 of the first substrate 12 that is in mechanical contact with the plastically deformable superconductor layer 14 and a region of the structured superconductor metallization 26 of the second substrate 16 that is in mechanical contact with the plastically deformable superconductor layer 14 are parallel to each other. In other words, the structured superconductor metallizations 24, 26 of the first and second substrate 12, 16 may be parallel to each other at a mechanical contact with the plastically deformable superconductor layer 14.

According to a further embodiment, the surfaces 24-A, 26-A of the structured superconductor metallizations 24, 26 may be formed as inclined or sloped surfaces. In order to adjust (set) the distance and orientation of the two substrates 12, 16 with respect to each other, at least one of the elevations 20-1, 20-2, 28-1, 28-2 of the topographic structure 20, 28 of the first and second substrate 12, 16 may function as (additional) abutment element or spacer on the first and/or second substrate 12, 16 during (and after) the step 120 of exerting (mechanical) pressure.

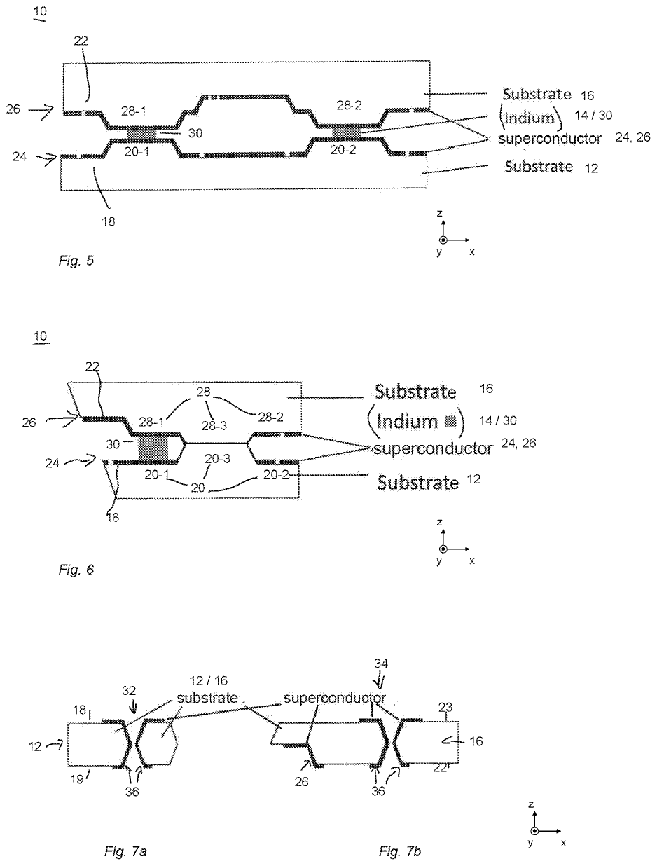

According to an embodiment, at least one respective topographic structure 20, 28 of the first and second substrates 12, 16 has a (e.g., monolithic) multi-level structure (e.g., a stepped multilayer structure), in which parallel surfaces of the different planes of the respective topographic structure 28 are arranged at different (e.g., vertical) heights (levels or planes) relative to each other (see, for example, FIG. 5), e.g., wherein the parallel surfaces of the respective topographic structure 28 are parallel to at least one surface of the other one of the first and second substrates 12, 16.

According to an embodiment, topographic structures 20, 28 of the first and/or second substrate 12, 16 comprise multilayered or multilevel structures with surfaces that are parallel to each other, e.g., one or more topographic structure 20, 26 having a stepped surface.

For example, the respective topographic structure 20, 28 may comprise two, three, four, five, or more layers or levels (planes), wherein the surfaces of the topographic structures 20, 28 extend along said layers or levels. Two levels (planes) may be connected by a vertical flank (or wall), (e.g., extending along a vertical direction). Alternatively or additional two levels may be connected by a slope. For example, the levels may extend parallel to a (100) surface of a silicon substrate, wherein, for example, anisotropic etching may result in one or more (111) planes with an angle of 54.74° relative to the (100) surface. The (111) may subsequently form sloped connection between the levels along the (100) surfaces.

According to an embodiment, the plastically deformable superconductor layer 14 extends between a parallel surface of the topographic structure 20 of the first substrate 12 that has (e.g., vertically) a smallest distance to the main surface of the second substrate 16 (e.g., a smallest distance to a parallel surface of the second topographic structure 28), e.g., wherein the step 120 of exerting pressure is performed until a compression criteria is met, e.g., a compression criteria related to a compression force and/or compression time.

According to an embodiment, the plastically deformable superconductor layer 14 (e.g., the mechanical and electrical superconductor connection 30 after the step 120 of exerting pressure) may be arranged at one or more elevations 20-1, 20-2 of the topographic structures 20 of the first substrate. Optionally, the plastically deformable superconductor layer (e.g., the mechanical and electrical superconductor connection after the step of exerting pressure) may be arranged at laterally coinciding elevations of the topographic structures 20, 28 of the first substrate 12 and second substrate 16. In other words, the first and second substrate 12, 16 may be connected, e.g., via the mechanical and electrical superconductor connection, at elevations 20-1, 20-2, 28-1, 28-2 of the topographic structures 20, 28 of the first and/or second substrate 12, 16.

For example, the topographic structure 20 of the first substrate 12 may comprise an elevation 20-1 with a flat surface and the second substrate 16 may comprise a flat surface (e.g., main surface), wherein the plastically deformable superconductor layer 14 is arranged between a structured superconductor metallization 24 on the elevation 20-1 of the first substrate 12 and a structured superconductor metallization 26 of the flat surface 22 of the second substrate 16. Due to its elevation (vertical height), the flat surface of the elevation 20-1 of the first substrate 12 is the surface with the smallest distance to the main surface 22 of the second substrate 16 (see, for example, FIG. 3a-d).

In a different example, the first substrate 12 comprises a topographic structure 20 with an elevation 20-1 and the second substrate 16 comprises a topographic structure 28 with an elevation 28-1 (see, for example, FIG. 4a-d or FIG. 5). The two elevations 20-1, 28-1 (20-2 and 28-2) may subsequently have the smallest distance between the first and second substrate 12, 16. Therefore, the two elevations 20-1, 28-1 may respectively comprise a structured superconductor metallization 24, 26 and the plastically deformable superconductor layer 14 may be arranged between the structured superconductor metallizations 24, 26 of the elevations 20-1, 20-2 of the first and second substrate 12, 16.

The structured superconductor metallizations 24, 26 of the first and second substrate 12, 16 may be arranged at highest (e.g., furthest away from the respective backside surface) levels of the respective multi-level topographic structure (or on a flat surface of the main surface if no topographic structure is provided).

It is noted that an elevation may also be described by a recess next to a non-recessed region. Therefore, the examples described herein with one or more elevations may similarly be described with one or more recesses.

Since no other surface with a smaller distance may be provided, an abutment of other surfaces of the first and second substrate 12, 16 may not block the compression of the plastically deformable superconductor layer 14. The compression may be performed until one or more compression thresholds are fulfilled. The compression thresholds may comprise a threshold for one or more of a distance between the first and second substrate 12, 16, a compression force, a compression pressure, a lateral extension of the plastically deformable superconductor layer 14, and an electrical resistance of the plastically deformable superconductor layer 14.

According to an embodiment, as exemplarily shown in FIG. 6, the plastically deformable superconductor layer 14 is arranged at (extends from) a parallel surface 20-1 of the topographic structure of the first substrate 12 that has a (e.g., vertical) distance to the main surface 28-3 of the second substrate 16 that is larger than a smallest (e.g., vertical) distance between the main surfaces 20-3, 28-3 of the first and second substrate 12, 16. The step 120 of exerting pressure can be performed until the main surfaces 20-3, 28-3 of the first and second substrate 12, 16 mechanically contact (abut to) each other.

According to an embodiment, the plastically deformable superconductor layer 14 is arranged at a recess 20-1, 28-1 of the topographic structure 20, 28 of the first and/or second substrate 12, 16. Before the step 120 of exerting pressure 27 to the first and second substrates 12, 16 is conducted, the plastically deformable superconductor layer 14 may have a (vertical) height that is larger than a (vertical) depth of the recess 20-1, 28-1 of the first or second substrate 12, 16 or may be larger than a combined (vertical) depth of the recesses 20-1 and 28-1 of the first and second substrate 12, 16. In other words, the mechanical and electrical superconductor connection 30 may be formed in recesses 20-1, 28-1 of the first and/or second substrate 12, 16.

For example, the topographic structure 20 of the first substrate 12 may comprise a recess and the second substrate 16 may comprise a flat (plane) surface 22. The recess 20-1 of the first substrate 12 has a distance to the main surface 22 of the second substrate 16 that is larger than a distance of a non-recessed region 18 of the first substrate 12 to the main surface 22 of the second substrate 16 (e.g., assuming a parallel orientation of the first and second substrates 12,16, e.g., parallel orientation of flat surfaces having the plastically deformable superconductor layer 14).

Similarly, the second substrate 16 may also comprise a topographic structure 28, e.g., with a further recess 28-1 (28-2, . . . ). The (vertically opposing) recesses 20-1, 28-1 (20-2, 28-2, . . . ) of the first and second substrate 12, 16 may therefore form a cavity when the first and second substrates 12, 16 are connected at the non-recessed surfaces. The recessed surfaces 20-1, 28-1 (20-2, 28-2, . . . ) may comprise structured superconductor metallizations 24, 26, which may be in contact with the plastically deformable superconductor layer 14. As a result, the non-recessed surfaces 20-3, 28-3 of the first and second substrates 12, 16 may abut against each other, wherein the opposing surfaces within the recesses 20-1, 28-1, and 20-2, 28-2 cannot abut against each other.

The structured superconductor metallizations 24, 26 of the first and second substrate 12, 16 may be arranged at levels (planes) that are not the (vertically) highest (e.g., furthest away from the respective backside surface) levels of the respective multi-level topographic structure 20, 28 (or on a flat surface of the main surface 18, 22 if no topographic structure 20, 28 is provided).

Before the step 120 of exerting pressure 27 to the first and second substrate 12, 16, the plastically deformable superconductor layer 14 (e.g., in its uncompressed state) may have a height, e.g., in vertical direction, that is large enough to prevent surface regions of the main surfaces 18, 22 of the first and second substrate 12, 16 that have the smallest (e.g., vertical) distance between the main surfaces 18, 22 of the first and second substrate 12, 16 to not abut against each other. In other words, the plastically deformable superconductor layer 14 (e.g., in its uncompressed state) may have a (vertical) height such that the first and second substrate 12, 16 do not directly contact each other.

For example, the first substrate 12 may comprise a recess 20-1 and the main surface 22 of the second substrate 16 is a flat surface, wherein the (vertical) height of the plastically deformable superconductor layer 14 exceeds a (vertical) depth of the recess of the first substrate 12. In other words, the plastically deformable superconductor layer 14 may extend out of the recess 20-1 and higher than the non-recessed region. In a different example, the first substrate 12 comprises a recess 20-1 and the second substrate 16 comprises a recess 28-1 that laterally coincides with the recess 20-1 of the first substrate 12. The plastically deformable superconductor layer 14 may be arranged in one (or as portions in both) of the recesses 20-1, 28-1, wherein a (e.g., vertical) height of the plastically deformable superconductor layer 14 exceeds a combined depth of the two (vertically opposing) recesses 20-1, 28-1.

In such a case, the step 120 of exerting pressure 27 to the first and second substrate 12, 16 may compress the plastically deformable superconductor layer 14 until surfaces with a smaller (vertical) distance (e.g., non-recessed surfaces) of the first and second substrate 12, 16 abut against each other. Therefore, the (vertical) distance between the structured superconductor metallizations 24, 26 that sandwich the plastically deformable superconductor layer 14 can be controlled accurately by the (vertical) depths of the one or more recesses or corresponding elevations 20-1, 28-1 (20-2, 28-2, . . . ).

According to an embodiment, the step 110 of providing the stack structure 10′ may comprise at least one of forming the topographic structure 20 of the main surface 18 of the first substrate 12 using etching (e.g., etching the first substrate 12, e.g., anisotropic etching), and (optionally) forming the topographic structure 28 of the main surface 22 of the second substrate 16 using etching (e.g., etching the second substrate 16, e.g., anisotropic etching).

According to an embodiment, the method 100 comprises the step 140 of forming the topographic structure 20, 28 of at least one of the first and second substrate 12, 16, e.g., using etching.

The step of etching may comprise forming a structured masking layer (e.g., that protects against etching or slows down etching), e.g., using a lithographic fabrication process. The etching may comprise etching (e.g., and therefore removal of) material of the first and/or second substrate 12, 16. The etching may comprise wet etching and/or dry etching. For example, a structured masking layer may be formed on a masked surface of the main surface 18, 22 of the first and/or second substrate 12, 16, wherein etching removes substrate material at areas not covered by the structured masking layer. After removal of the structured masking layer, areas previously covered by the structured masking layer may subsequently form elevations relative to the etched areas (or in other words: areas not covered by the structured masking material may form recesses relative to covered areas).

More than one etching procedures, e.g., comprising forming a structured masking layer, etching, and removal of the structured masking layer, may be performed, e.g., in order to form a topographic structure 20, 28 with multiple levels or planes.

According to an embodiment, the first substrate comprises (or consists of) monocrystalline silicon with (e.g., the main surface having) a (100)-silicon surface and forming the topographic structure of the first substrate comprises forming {111}-planes using anisotropic etching, and/or the second substrate comprises (or consists of) monocrystalline silicon with (e.g., the second main surface having) a (100)-silicon surface and forming the topographic structure of the second substrate comprises forming {111}-planes using anisotropic etching.

According to an embodiment, forming the topographic structure of the first and/or second substrate may comprise anisotropic etching.

The (100)-silicon layer may extend along the lateral directions. Etching in a vertical direction may result in slanted surfaces due to different etching rates for different directions during anisotropic etching.

According to an embodiment, the step 110 of providing the stack structure 10′ comprises at least one of forming the structured superconductor metallization 24 on the main surface 18 of the first substrate 12 using a lithographic fabrication process (e.g., comprising lithographic patterning and depositing of a superconductor metal), and forming the structured superconductor metallization 26 on the main surface 22 of the second substrate 16 using a lithographic fabrication process (e.g., comprising lithographic patterning and depositing of a superconductor metal).

According to an embodiment, the step 110 of providing the stack structure 10′ may comprise forming the structured superconductor metallization 24, 26 of at least one of the first and second substrate 12, 16.

A lateral structure of the structured superconductor metallization 24, 26 may be realized based on a lateral structure of a photoresist. A thickness (or vertical height) of the structured superconductor metallization 24, 26 may be realized based on a deposition amount and/or time. Deposition of material for the structured superconductor metallization 24, 26 may comprise one or more of physical vapor deposition, chemical vapor deposition, molecular beam epitaxy, laser ablation or other methods for material deposition.

According to an embodiment, forming the structured superconductor metallization 24, 26 of the first and/or second substrate 12, 16 comprises depositing a nucleation layer (seed layer or intermediate layer), e.g., Ti (titanium) or TiN (titanium nitride) or an intermetallic compound (IMC), e.g. as an under-bump metallization 24a, 26a, on the corresponding main surface, and depositing a superconductor metal (e.g., tantalum, e.g., alpha tantalum, e.g., different from a material of the plastically deformable superconductor layer 14) on the nucleation layer.

According to an embodiment, forming the structured superconductor metallization 24, 26 comprises depositing more than one consecutive layer of different material compositions, e.g., a first layer comprising titanium and a second layer comprising tantalum.

In order to be able to form or deposit the superconducting contact areas 24, 26 on the first and second substrates 12, 16, it may be supportive, for example, to apply a so-called intermediate layer (seed layer) or under-bump layer 24a, 26a on the surface area of the respective substrate 12, 16, whereby the respective superconducting material for the contact areas 24, 26 on the first and second or further substrates 12, 16 can then be applied or deposited, for example, in a CVD environment using precursors.

Based on the material of the superconducting structured metallization 24, 26 on the first or second substrate 12, 16, it may be necessary to apply the intermediate layer 24a, 26a with a suitable intermediate layer material, which enables/allows the application (deposition) of the superconducting material for the structured metallization(s) 24, 26. Thus, the structured superconductor metallizations (contact areas) 24, 26 may comprise a layer sequence or layer stack having a plurality (2 or 3 or . . . ) of different layers, wherein each of the layers comprise or consist of an electrically conductive and superconducting material (e.g. electrically conductive and superconducting material metal).

According to an embodiment, as exemplarily shown in FIGS. 3a-d and 4a-d, the step 110 of providing the stack structure 10′ may comprise one of the following alternatives: —(1) forming the plastically deformable superconductor layer 14 on the structured superconductor metallization 24 of the first substrate 12 (e.g., comprising lithographic patterning and depositing of the superconductor electrode material) and mechanically contacting the plastically deformable superconductor layer 14 between the structured superconductor metallizations 24, 26 of the first and second substrate 12, 16; —(2) forming the plastically deformable superconductor layer 14 on the second structured superconductor metallization 26 (e.g., comprising lithographic patterning and depositing of the superconductor electrode material) and mechanically contacting the plastically deformable superconductor layer 14 between the structured superconductor metallizations 24, 26 of the first and second substrate 12, 16; or —forming a first portion of the plastically deformable superconductor layer 14 on the structured superconductor metallization 24 of the first substrate 12 and a second portion of the plastically deformable superconductor layer 14 on the structured superconductor metallization 26 of the second substrate (e.g., comprising lithographic patterning and depositing of the superconductor electrode material), and mechanically contacting the first and second portion of the plastically deformable superconductor layer 14 to form the plastically deformable superconductor layer 14.

According to an aspect, the step 110 of providing the stack structure 10′ comprising forming the plastically deformable superconductor layer 14, e.g., on the structured superconductor metallizations 24, 26 of the first and/or second substrate 12, 16 (e.g., only on the structured superconductor metallization of one substrate or in portions on structured superconductor metallizations 24, 26 of the first and second substrate 12, 16).

The plastically deformable superconductor 14 may be formed using any method disclosed for the structured superconductor metallization.

According to an embodiment, the plastically deformable superconductor layer 14 comprises (e.g., or consists) of indium, and/or one or more structured superconductor metallizations 24, 26 of the first and/or second substrate 12, 16 comprise (e.g., consist of) one or more of niobium, aluminum, tantalum, titanium nitride, and indium.

According to an embodiment, the plastically deformable superconductor layer 14 comprises indium or an alloy (or material composition) comprising indium. Alternatively or additionally, the plastically deformable superconductor layer 14 may comprise other superconductor materials, e.g., one or more of niobium, aluminum, tantalum, lead, mercury, lanthanum, vanadium, and titanium nitride and/or non-superconductor materials, e.g., one or more silicon, gold, silver, nickel, copper, and oxide. Similarly, the structured superconductor metallizations 24, 26 may comprise or consist of superconductor materials and/or non-superconductor materials disclosed herein.

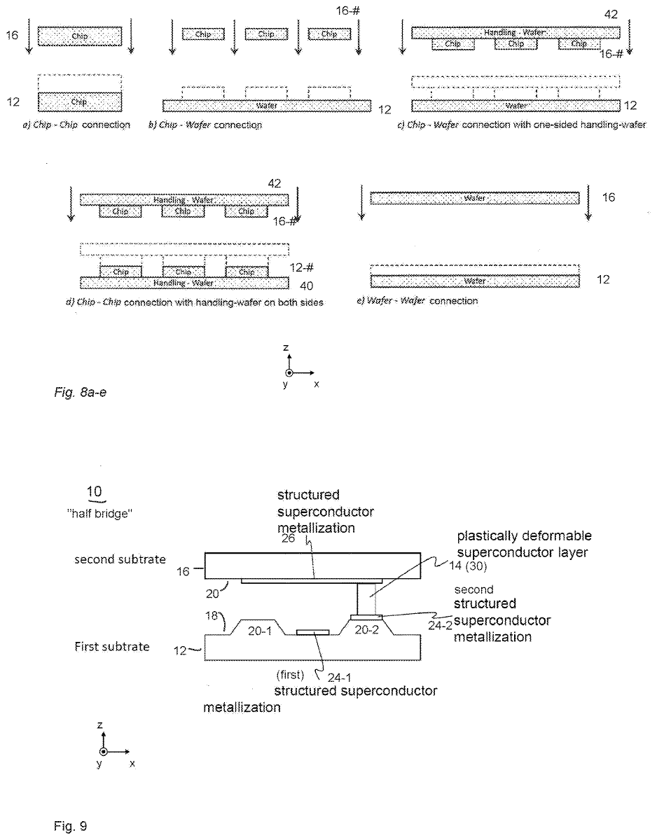

According to an embodiment, as exemplarily shown in FIG. 9, the main surface 18 of the first substrate 12 comprises a first structured superconductor metallization 24-1 that is electrically isolated from a second structured superconductor metallization 24-2 of the first substrate 12, wherein the first structured superconductor metallization 24-1 of the first substrate 12 laterally overlaps with (vertically opposes), e.g., laterally traverses (e.g., without directly mechanically contacting each other) the structured superconductor metallization 26 of the second substrate 16.

According to an embodiment, the structured superconductor metallization 24 (24-1+24-2) of the first substrate 12, the plastically deformable superconductor layer 14 (e.g., the mechanical and electrical superconductor connection 30 after the step of exerting pressure), and the structured superconductor metallization 26 of the second substrate 16 form a half-bridge (e.g., traversing between the first and second substrate on one first lateral side of the first further structured superconductor metallization, but not necessarily on second lateral side opposite the first lateral side). The half-bridge may allow a lateral overlap (in vertical offset planes) and/or lateral traversal/crossing of the first structured superconductor metallization 24-1 and an conducting lead comprising the half-bridge, e.g., comprising the second structured superconductor metallization 24-2 of the first substrate 12, the plastically deformable superconductor layer 14, and the structured superconductor metallization 26 of the second substrate 16.

An electrical lead comprising the structured superconductor metallization 24-1 of the first substrate 12 can, thusly cross (or at least laterally overlap with) the structured superconductor metallization 26 of the second substrate 16 (e.g., without causing an electrical short), by essentially traversing (via the plastically deformable superconductor layer 14) to the second substrate 16. The electrical lead can continue along the second substrate 16 or traverse back to the first substrate 12 using a further plastically deformable superconductor layer 14 as described below (in the context of a full-bridge).

The first structured superconductor metallization 24-1 of the first substrate 12 may extend laterally perpendicular (e.g., or at an angle between 45° and 135° relative) to the structured superconductor metallization 26.

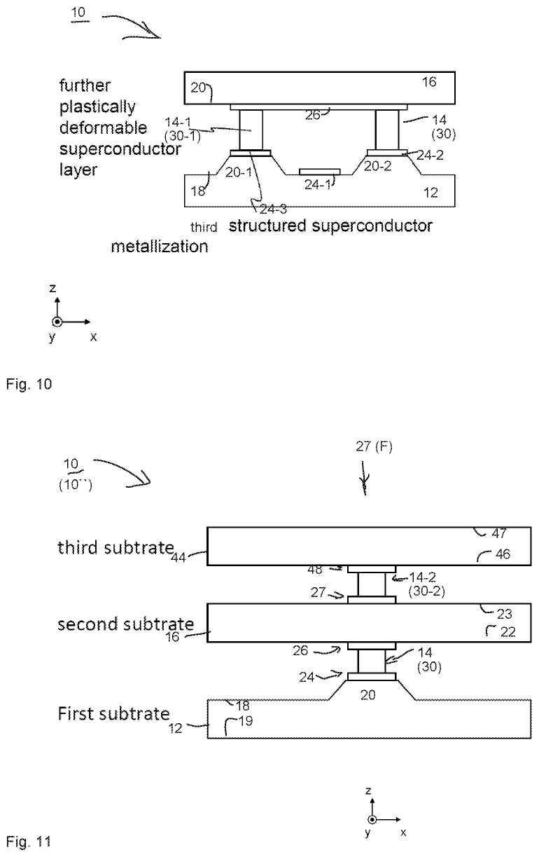

According to an embodiment, as exemplarily shown in FIG. 10 (full-bridge structure), the main surface 18 of the first substrate 12 comprises a third structured superconductor metallization 24-3 that is electrically isolated from the first and second structured superconductor metallization 24-1, 24-2 of the first substrate 12, wherein the first to third structured superconductor metallization 24-1, 24-2, 24-3 form together the structured superconductor metallization 24 of the first substrate 12. The second structured superconductor metallization 24-2 is arranged laterally between the first structured superconductor metallization 24-1 and the third structured superconductor metallization 24-3 of the first substrate 12, wherein the stack structure 10′ comprises a further plastically deformable superconductor layer 14-1 (e.g., electrically isolated from the plastically deformable superconductor layer) that extends between the third structured superconductor metallization 24-3 of the first substrate 12 and the structured superconductor metallization 26 of the second substrate 16.

The step 120 of exerting pressure 27 to the first and second substrate 12, 16 comprises compressing (e.g., applying a force to compress, e.g., one or both of the first and second substrate, e.g., cold-welding) —the plastically deformable superconductor layer 14 (e.g., by compressing the stack structure 10′) between the second structured superconductor metallization 24-2 of the first substrate 12 and the structured superconductor metallization 26 of the second substrate 16 and —compressing the further plastically deformable superconductor layer 14-1 (e.g., by compressing the stack structure) between the third structured superconductor metallization 24-3 of the first substrate 12 and the structured superconductor metallization 26 of the second substrate 16, in order to form a first and second mechanical and electrical superconductor connection 30, 30-1 between the second and third structured superconductor metallization 24-2, 24-3 of the first substrate 12 and the structured superconductor metallization 26 of the second substrate 16.

According to an embodiment, the second structured superconductor metallization 24-2 of the first substrate 12, the plastically deformable superconductor layer 14 (e.g., the mechanical and electrical superconductor connection 30 after the step 120 of exerting pressure), the structured superconductor metallization 26 of the second substrate 16, the further plastically deformable superconductor layer 14-1 (e.g., the further mechanical and electrical superconductor connection 30-1 after the step 120 of exerting pressure), and the third structured superconductor metallization 24-3 of the first substrate 12 form a “full-bridge” (with respect to the first structured superconductor metallization 24-1 of the first substrate 12). E.g., the full-bridge may traverse between the first and second substrate 12, 16 on one first lateral side of the first structured superconductor metallization 24-1 and on a second lateral side opposite the first lateral side. The full-bridge may allow a lateral traversal/crossing of the first structured superconductor metallization 24-1 and a conducting lead comprising the full-bridge.

An electrical lead comprising the second and third structured superconductor metallization 24-2, 24-3 of the first substrate 12 can thusly cross the first structured superconductor metallization 24-1 of the first substrate 12 by traversing to (the vertically offset plane of) the second substrate 16 via the plastically deformable superconductor layer 14 (30) and traversing back to the first substrate 12 via the further plastically deformable superconductor layer 14-1 (30-1).

According to an embodiment, the method 100 further comprising at least one of forming the first structured superconductor metallization 24-1 on the first main surface 18 of the first substrate 12 using a lithographic fabrication process (e.g., comprising lithographic patterning and depositing of a superconductor metal), forming the second structured superconductor metallization 24-2 on the first main surface 18 of the first substrate 12 using a lithographic fabrication process (e.g., comprising lithographic patterning and depositing of a superconductor metal), forming the plastically deformable superconductor layer 14 or a first portion thereof on the second structured superconductor metallization 24-2 of the first substrate 12 (e.g., comprising lithographic patterning and depositing of the superconductor electrode material); forming the further plastically deformable superconductor layer 14-1 or a second portion thereof on the structured superconductor metallization 26 of the second substrate 16 (e.g., comprising lithographic patterning and depositing of the superconductor electrode material).

According to an embodiment, the method 100 may comprise forming (e.g., components of) the half-bridge or full bridge.

According to an embodiment, as exemplarily shown in FIG. 7a, the stack structure 10′ comprises at least one of a via 32, e.g. a TSV (through silicon via), extending through the first substrate 12 and a superconductor connection 36 through the via 32 of the first substrate 12 that electrically (and superconductive) connects a portion of first main surface 18 of the first substrate 12, e.g., a structured superconductor metallization 24 thereof, with a portion of a backside surface 19 of the first substrate 12 that is opposite of the main surface 18.

As exemplarily shown in FIG. 7b a (further) via 34 extends through the second substrate 16 and a superconductor connection through the via 34 of the second substrate 16 that electrically (and superconductive) connects a portion of the main surface 22 of the second substrate 16, e.g., a structured superconductor metallization 26 thereof (e.g., the second structured superconductor metallization) with a portion of a backside surface 23 of the second substrate 16 that is opposite of the main surface 22 of the second substrate 16.

According to an embodiment, the method 100 may comprise forming at least one via 32, 34 through the first and/or second substrate 12, 16, e.g., any number of vias 32 through the first substrate 12 and any number of vias 34 through the second substrate 16.

The via 32, 34 may be formed by etching only at the main surface 18, 22, only at the backside surface 19, 23, or at both, the main surface 18, 22 and the back surface 19, 23 of the first and/or second substrate 12, 16. For example, the first and/or substrate 12, 16 may comprise (or consists of) monocrystalline silicon with (e.g., the main surface having) a (100)-silicon surface and forming the via 32, 34 of the first and/or second substrate 12, 16 comprises forming {111}-planes using anisotropic etching. Inner surfaces of the via 32, 34 may have an angle or 54.74° (e.g., within an error or tolerance range of ±5%) relative to the main surface 18, 22 and/or backside surface 19, 23 of the first and/or second substrate 12, 16. The first and/or second substrate 12, 16 may comprise more than one via 32, 34.

According to a further embodiment, the first and/or substrate 12, 16 may comprise (or consists of) any substrate material, wherein forming the via 32, 34 of the first and/or second substrate 12, 16 comprises forming vias 32, 34 having vertical or (slightly) inclined inner surfaces relative to the main surface 18, 22 and/or backside surface 19, 23 of the first and/or second substrate 12, 16. The first and/or second substrate 12, 16 may comprise more than one via 32, 34.

According to an embodiment, the method 100 comprises forming the via 32 of the first substrate 12 using etching the first substrate 12 (e.g., anisotropic etching) and forming (depositing) a superconductor material in the via 32 or on a surface inside the via 32 of the first substrate 12, and/or forming the via 34 of the second substrate 16 using etching the second substrate 16 (e.g., anisotropic etching) and forming (depositing) a superconductor material in the via 34 or on a surface inside the via 34 of the second substrate 16.

According to an embodiment, the method 100 comprises etching and/or material depositing for forming the one or more vias 32, 34, e.g., through the first and/or second substrate 12, 16.

Forming the via 32, 34 may comprise any etching step disclosed herein with reference to forming the topographic structure 24, 28 of the first and/or second substrate 12, 16.

According to an embodiment, as exemplarily shown in FIGS. 8b-e, the method 100 comprises attaching (mechanically coupling/connecting) the first substrate 12 to a first handling wafer 40 before the step 120 of exerting pressure to the first and second substrate 12, 16, and detaching (separating or disconnecting) the first substrate 12 from the first handling wafer 40 after the step 120 of exerting pressure to the first and second substrate 12, 16, and/or attaching (mechanically coupling/connecting) the second substrate 16 to a second handling wafer 42 before the step 120 of exerting pressure to the first and second substrate 12, 16, and detaching (separating or disconnecting) the second substrate 16 from the second handling wafer 42 after the step 120 of exerting pressure to the first and second substrate 12, 16.

According to an embodiment, the first and/or second substrate 12, 16 are respectively temporarily attached/connected to a respective handling wafer 40, 42.

The step 120 of exerting pressure to the first and second substrate 12, 16 may comprise exerting pressure (or force) on one or both of the first and second handing wafers 40, 42. The first and/or second handling wafer 40, 42 may be used for one or more of, flipping a substrate over (e.g., by 180°), arranging the second substrate 16 relative to the first substrate 12, e.g., in a lateral and/or vertical direction, and exerting pressure to the first and second substrate 12, 16.

According to an embodiment, the stack structure 10′ may comprises one or more further (second) substrates 16-#(16-1, . . . ) laterally separate from the second substrate 16, wherein each respective further substrate 16-# of the one or more further substrates 16-# has a corresponding main surface 22-# facing the main surface 18 of the first substrate 12, a corresponding structured superconductor metallization 26-# on the corresponding main surface 22-#, and a corresponding plastically deformable superconductor layer 14-# extending between the corresponding structured superconductor metallization 26-# of the respective further (second) substrate 16-# and the structured superconductor metallization 24 of the first substrate 12.

The method 100 further comprises the step 120 of exerting pressure 27 to the first substrate 12 and the one or more further (second) substrates 16-# for respectively compressing, e.g., applying a force F to compress (e.g., to one or both of the first and second substrates 12, 16, e.g., cold-welding) the corresponding further plastically deformable superconductor layer 14-#, e.g., by moving (pressing) the first and further second substrate 12, 16-# towards each other, between the structured superconductor metallizations 24, 26-# of the first and respective further substrate 12, 16-# in order to form a corresponding mechanical and electrical superconductor connection 30, 30-# between the structured superconductor metallizations 24, 26, 26-# of the first substrate 12 and the respective further second substrate 16, 16-#.

According to an embodiment, a plurality of further (second) substrates 16, 16-# are arranged on (e.g., attached to, bonded to, connected with) a common first substrate 12.

For example, the first substrate 12 may be a wafer onto which a plurality of second substrates 16, 16-# are attached. The wafer 12 may optionally be cut (separated or singulated) into a plurality of dices 10, wherein each dice 10 may have one second substrate 16, 16-#(or any other number of second substrates 16, 16-#, such as zero, two, or more).

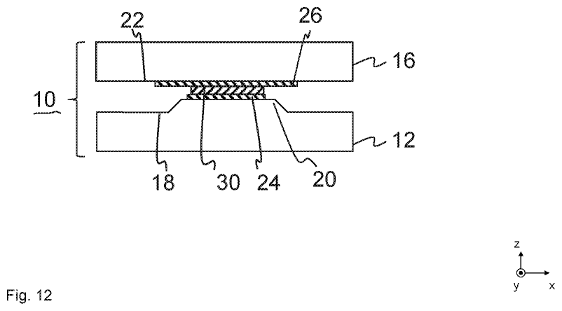

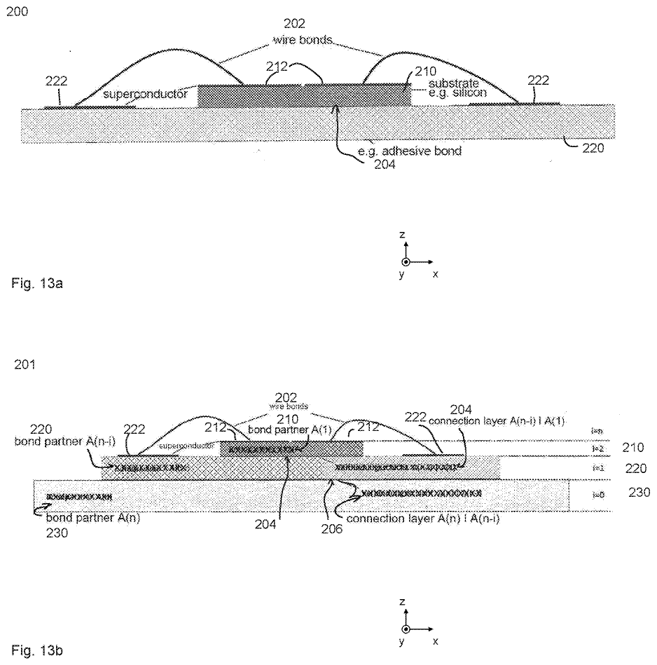

According to an embodiment, as exemplarily shown in FIG. 11, the method comprises providing an expanded stack structure 10″ that comprises the first and second substrate 12, 16, e.g. the stack structure 10′ of FIG. 2a or the substrate structure 10 of FIG. 2b (e.g., after the step 120 of exerting force F) with the plastically deformable superconductor layer 14, a third substrate 44, and a second plastically deformable superconductor layer 14-2, wherein the second substrate 16 comprises a backside surface 23 opposite to the main surface 22 of the second substrate 16. The backside surface 23 of the second substrate 16 comprises a backside structured superconductor metallization 27. The third substrate 44 comprises a main surface 46 facing the backside surface 27 of the second substrate 16 and having a structured superconductor metallization 48, wherein the second plastically deformable superconductor layer 14-2 extends between the backside structured superconductor metallization 27 of the second substrate 16 and the structured superconductor metallization 48 of the third substrate 44. The method 100 further comprises the step 120 of exerting pressure 27 to expanded stack structure 10″ (e.g. to the second substrate 16 and the third substrate 16 or between the first substrate 12 and the third substrate 16) for compressing (e.g., applying a force F to compress, e.g., to one or both of the second and third substrate 16, 44 or the first and third substrate 12, 44, e.g., cold-welding) the second plastically deformable superconductor layer 14-2 (e.g., by moving the first and third substrate 12, 44 or the second and third substrate 16, 44 towards each other) between the structured superconductor metallizations 27, 48 of the second and third substrate 16, 44 in order to form a mechanical and electrical superconductor connection 30-2 between the structured superconductor metallizations 27, 48 of the second substrate 16 and the third substrate 44.

According to an embodiment, the method 100 comprises forming a vertical stack (the expanded stack structure) 10″ with a third substrate 44. In other words, the method 100 may comprise bonding or attaching further substrates 44 (e.g., the third substrate) on top of the second substrate 16 (e.g., bonding to the backside surface 27 of the second substrate 16). The steps 120 of exerting pressure to the first and second substrate 12, 16 and the step 120 of exerting pressure to the second and third substrate 16, 44 may be performed simultaneously or consecutively.

For example, the method 100 may comprise providing the first, second, and third substrates 12, 16, 44, the plastically deformable superconductor layer 14, and the further the plastically deformable superconductor layer 14-2 (e.g., as described herein, e.g., alternating between substrates and plastically deformable superconductor layers), wherein a pressure F is applied to the first and third substrate 12, 44, e.g., and therefore indirectly also to the second substrate 16, in order to compress the plastically deformable superconductor layer 14 and the further the plastically deformable superconductor layer 14-2 at the same time (e.g., simultaneously).

In a different example, the first and second substrate 12, 16 and the plastically deformable superconductor layer 14 are provided (e.g., as described herein) and a pressure F is exerted (step 120) for compressing the plastically deformable superconductor layer 14. Afterwards, the further plastically deformable superconductor 14-2 and the third substrate 44 are provided, i.e. wherein the plastically deformable superconductor layer 14 has already been compressed, and subsequently a pressure F is exerted for compressing the further plastically deformable superconductor 14-2.

The method 100 essentially allows forming a stack 10 of more than two substrates 12, 16 by attaching a third substrate 44 on top of the second substrate 16 (thusly forming an expanded stack 10″ having mechanical and electrical superconductor connections 14, 14-2 between two pairs of substrates 12, 16 and 16, 44). However, the third substrate 44 may alternatively be attached to the first substrate 12. Furthermore, the method 100 for attaching additional substrates 44 may be iteratively repeated in order to stack more substrates on top of each other. For example, a fourth substrate may be attached to the third substrate 44, for example, wherein a fifth substrate may be attached to the fourth substrate. Therefore, a stack with any number of substrates stacked on top of each other can be fabricated. According to an embodiment, the main surface 22 of the second substrate 16 may (optionally) also have a topographic structure 28. According to a further embodiment, the main surface 46 of the third substrate 44 may (optionally) also have a topographic structure.

According to an embodiment, as exemplarily shown in FIG. 12, a substrate structure 10 comprises a stack structure 10′ comprising a first substrate 12 (e.g., silicon substrate), a plastically deformable superconductor layer 14 (e.g., comprising or consisting of indium), and a second substrate 16 (e.g., silicon substrate). The first substrate 12 has a main surface 18 with a topographic structure 20 and the second substrate 16 (e.g., silicon substrate) has a main surface 22 facing the main surface 18 of the first substrate 16. According to an embodiment, the main surface 22 of the second substrate 16 may (optionally) also have a topographic structure 28.

The main surface 18 and e.g., at least a portion of the topographic structure 20 of the first substrate 12 comprises a structured superconductor metallization 24, e.g., comprising one or more of following materials: Al, Nb, Ta, TiN, and the main surface 22 of the second substrate 16 comprises a structured superconductor metallization 26, e.g., comprising one or more of the following materials: Al, Nb, Ta, TiN, and a (compressed) plastically deformable superconductor layer 14 (e.g., which is compressed by moving the first and second substrate 12, 16 towards each other). The plastically deformable superconductor layer 14 extends between the structured superconductor metallizations 24, 26 of the first and second substrates 12, 16 in order to provide a mechanical and electrical superconductor connection 30 between the structured superconductor metallizations 24, 26 of the first and second substrates 12, 16.

The substrate structure 10 may be formed by any method disclosed herein. Therefore, the substrate structure 10 may comprise any feature disclosed herein with reference any method disclosed herein, e.g., comprising one or more of multi-layered structures, vias, a half-bridge, a full bridge, the being arranged on a recess and/or an elevation.

According to an embodiment, the stack structure 10′ may comprise one or more further (second) substrates 16-# laterally separated from the second substrate 16, wherein each respective further substrate 16-# of the one or more further second substrates has a corresponding main surface 22-# facing the main surface 18 of the first substrate 12, a corresponding structured superconductor metallization 26-# on the corresponding main surface 22-#, and a corresponding plastically deformable superconductor layer 14-# extending between the corresponding structured superconductor metallization 26-# of the respective further substrate 16-# and the structured superconductor metallization 24 of the first substrate 12. The stack structure 10′ may further comprise one or more compressed corresponding further plastically deformable superconductor layers 14-#(e.g., compressed by moving the first and second substrate 12, 16 towards each other) respectively extending between the structured superconductor metallization(s) 24 of the first substrate 12 and the corresponding structured superconductor metallization 26-# of the respective further second substrate 16-# in order to provide a corresponding mechanical and electrical superconductor connection 30, 30-# between the structured superconductor metallization(s) 24 of the first substrate 12 and the corresponding structured superconductor metallization(s) 26, 26-# of the respective further second substrate 16, 16-#.

According to an embodiment, the substrate structure 10 may comprise a plurality of second substrates 16, 16-# connected to (e.g., bonded with) a common first substrate 12.

According to an embodiment, the substrate structure 10 may comprise as described herein, a third substrate 44, wherein the second substrate 16 comprises a backside surface 23 opposite the main surface 22 of the second substrate 16 and the backside surface 23 of the second substrate 16 comprises a backside structured superconductor metallization 27. The third substrate 44 comprises a main surface 46 facing the backside surface 23 of the second substrate 16 and having a structured superconductor metallization 48, wherein a second compressed plastically deformable superconductor layer 14-2 (e.g., compressed by moving the first and second substrate 12, 16 towards each other) extends between the structured superconductor metallizations 27, 48 of the second and third substrates 16, 44 in order to provide a second mechanical and electrical superconductor connection 30-2 between the structured superconductor metallizations 27, 48 of the second and third substrates 16, 48.

According to an embodiment, the substrate structure 10 may formed from an expanded structure 10″ having a vertical stack with multiple substrates 12, 16, 44, e.g., the first, second, and third substrates 12, 16, 44 and optionally further substrates.

According to an embodiment, an ion trap, quantum computing device (or quantum computer) or a superconducting quantum interference device comprising one or more of the any substrate structure and/or expanded stack structure disclosed herein.

Before describing further embodiments of the present disclosure, it should be noted that in the present description of embodiments, same or similar elements (method steps) having the same function are provided with the same reference numbers or the same name, wherein a detailed description of such elements will not be repeated for every embodiment. Thus, the above description is equally applicable to the further embodiments as described below. In the following description, different implementations of the embodiments and, essentially, the differences, e.g. additional or different elements, method steps and/or structures, and the technical effect(s) resulting therefrom are discussed in detail.

As described above in connection with FIGS. 1 and 2a-b, the respective topographic structures 20, 28 of the first and/or second substrate 12, 16 may comprise different levels or planes, wherein the surfaces of the topographic structures 20, 28 extend along said levels or planes. Two levels (planes) may be connected by a slope or sloped surface region. For example, the levels may extend parallel to a (100) surface of a silicon substrate, wherein, for example, anisotropic etching may result in one or more (111) planes with an angle of 54.74° relative to the (100) surface. The (111) may subsequently form sloped connection between the levels along the (100) surfaces.

In the following, exemplary embodiments for structuring of the respective substrate 12, 16, 44 and providing the respective topographic structures 20, 28 thereof are described.
The substrate 12, 16, 44 may consist of (or comprise) a monocrystalline silicon wafer (e.g., or any other crystalline structure and/or material), advantageously with a high specific resistance in order to avoid electrical losses in the conductive layer.
A lithography step may be used to create masking layers of any lateral geometry in the substrate 12, 16, 44.
KOH or TMAH etching processes (or any other etching process) may be used to etch structures 20, 28 in the respective substrate 12, 16, 44, e.g., that are as atomically smooth as possible, e.g., and have a defined angle of the side walls.
The etching depth and, thus, the resulting topography height may be precisely determined for these etching processes and may therefore be set as required, e.g., based on one or more etching parameters such as etching agent, etching duration, etching temperature, and crystal orientation.
By using several mask steps, different depths and geometrically different structures 20, 28 may be created, e.g. for conductor track crossings or capacitive couplings. This creates the topographical structure(s) 20, 28. However, the method may not necessarily comprise the formation of the topographic structure(s). For example, the topographic structure(s) may have already been provided.
The specific angle of inclination between the different planes (levels) of the topographic structures 20, 28, e.g. the (111) plane and the (100) plane, can be approximately 54.74°. The angle changes in case of different substrate orientations. This angle ensures good coverage (covering) of the etching flanks for all subsequent deposition methods. However, other planes and angles as well as the use of non-monocrystalline substrate material may be possible. The surfaces 18, 22, . . . can, for example, be post-treated by thermal oxidation or hydrogen annealing to further optimize the surface quality.
The edges of the topographic structures 20, 28 can optionally be rounded by thermal oxidation.

In the following, exemplary embodiments for providing a metallization on the respective substrate 12, 16, 44 or the respective topographic structures 20, 28 thereof are described.

The metallization 24, 26, 48 (e.g., by forming a structured superconductor metallization) of the substrate 12, 16, 44 may consist of or comprise the known superconducting materials (e.g. Al, Nb, Ta, TiN, In or others) and may be carried out using known deposition and structuring methods.

In the following, exemplary embodiments for bonding the respective substrates 12, 16, 44 are described.

Vertical contacting of the chips using flip-chip, wafer-chip and wafer-wafer bonding processes or others. The bonding may comprise exerting pressure to the first and second substrate for compressing the plastically deformable superconductor layer. Flip-chip may denote a method wherein one of the first and second substrate is flipped over in order for its main surface to face the main surface of the other one of the first and second substrate and forming a mechanical bond with an electrical and superconducting connection between metallizations of the first and second substrate.

Before describing further embodiments of the present disclosure, it should be noted that in the present description of embodiments, same or similar elements having the same structure and/or function are provided with the same reference numbers or the same name, wherein a detailed description of such elements will not be repeated for every embodiment. Thus, the above description of the MEMS device 100 with respect to FIG. 1a is equally applicable to the further embodiments as described below. In the following description, different implementations of the embodiments of the MEMS device 100 of FIG. 1a and, essentially, the differences, e.g. additional elements and/or structures, and the technical effect(s) resulting therefrom are discussed in detail.

In the following, further exemplary embodiments of the substrate structure 10 and of the method 100 for fabricating such a substrate structure 100 are described in detail while making reference to the accompanying drawings.

FIGS. 3a-d show different schematic cross-sectional views of a superconducting chip-to-chip connection process (method) 100 of a (substrate structure 10 having a) topographically structured substrate 12 and a planar substrate 16 according to an embodiment of the present disclosure.

FIGS. 3a-c exemplarily show the step 110 of providing a stack structure 10′, wherein FIG. 3d shows the provided stack structure 10′ in a bonded condition, such as after (or during) the step 120 of exerting (mechanical) pressure F to the first and second substrate 12, 16, e.g. by flip-chip technology.

As exemplarily shown in FIGS. 3a-d, the first substrate 12 may have the topographic structure 20 and the second substrate 16 may have a flat main surface 22, each with a structured superconducting metallization 24, 26 (e.g. structured superconductor metallizations). The contact 30 (e.g., in form of a mechanical and electrical superconductor connection) is made with the mechanically deformable connection layer 14 (e.g., a plastically deformable superconductor layer) made of or comprising e.g. indium for e.g. superconducting quantum devices.

In other words, a further embodiment of the method 100 for fabricating the substrate structure 10 is provided. The method 100, as shown in FIGS. 3a-d, comprises the step 110 of providing the stack structure 10′ comprising a first substrate 12, a plastically deformable superconductor layer 14, and a second substrate 16, wherein the first substrate 12 has a main surface 18 with a topographic structure 20 and the second substrate 16 has a main surface 22 facing the main surface 18 of the first substrate 12. The main surface 18 of the first substrate 12 comprises a structured superconductor metallization 24 and the main surface 22 of the second substrate 18 comprises a structured superconductor metallization 26, wherein the plastically deformable superconductor layer 14 is arranged (extends) between the structured superconductor metallization 24 of the first substrate 12 and the structured superconductor metallization 26 of the second substrate 18. The method further comprises the step 120 of exerting pressure F to the first and second substrate 12, 16 for compressing the plastically deformable superconductor layer 14 between the structured superconductor metallizations 24, 26 of the first and second substrates 12, 16 in order to form a mechanical and electrical superconductor connection 30 between the structured superconductor metallizations 24, 26 of the first and second substrates 12, 16.

The plastically deformable superconductor layer 14 may initially be formed on the structured superconductor metallization 24 of the first substrate (e.g., see FIG. 3b), on the structured superconductor metallization 26 of the second substrate 16 (e.g., see FIG. 3c), or a portion of the plastically deformable superconductor layer 14 may be formed on the structured superconductor metallization 24 of the first substrate 12 and a further portion of the plastically deformable superconductor layer 14 may be formed on the structured superconductor metallization 26 of the second substrate 16 (e.g., see FIG. 3a).

FIGS. 3a-d exemplarily show a superconducting connection process (method) 100 between a topographically structured and a planar Si substrate 12, 16 created by a bonding process, e.g. by flip-chip technology, before the bonding process (FIG. 3a, 3b or 3c) and after the bonding process (FIG. 3d). Further optional bonding processes are, for example, chip to chip, chip to wafer or wafer to wafer bonding. Superconducting metals 24, 26 (e.g. Nb, TiN, Ta, Al) are present on both substrates 12, 16 before the bonding process and a superconducting mechanically deformable layer 14 (e.g. In) is present on one substrate (FIGS. 3b and 3c) or both substrates (FIG. 3a).

FIGS. 4a-d show different schematic cross sectional views of a superconducting chip-to-chip connection process (method) 100 of a (substrate structure 10 having a) two topographically structured substrates 12, 16 according to a further embodiment of the present disclosure.

FIGS. 4a-d show an example of the bond system (single bond) from FIG. 3 of options a, b, c with topographically structured substrates 12, 16 facing each other on both sides, e.g., a first substrate 12 having a topographic structure 24 and a second substrate 16 having a topographic structure 28. However, these systems can also be built/stacked in any height by structuring the substrates 12, 16 on both sides (multi-bond), e.g., by providing a third substrate 44 that is connected/bonded with a backside surface 23 of the second substrate 16.

The illustration of the method 100 based on FIGS. 4a-d differs from the illustration of the method 100 in FIGS. 3a-d in that both substrates 12, 16 are topographically structured on opposite sides, wherein both embodiments have in common the different options for placing the superconducting mechanically deformable layer 14 (see FIGS. 3a-d and FIGS. 4a-d).

Alternatively, substrates with multiple topographical structures can also be used, e.g., topographic structures with more than two layers (e.g., alternatively to having a topographic structure with only one or two levels or planes).

FIG. 5 shows a schematic cross sectional view of a substrate structure 10 having a two topographically structured substrates 12, 16 in a connected state according to a further embodiment of the present disclosure.

Accordingly, FIG. 5 shows a schematic representation of chip-to-chip connection, e.g. contacted by flip-chip, of a two-level (single-step) topographically structured substrate 12 with a structured superconducting metallization 26 with a three-level topographically structured substrate 16 with a structured superconducting metallization 26. As exemplarily shown in FIG. 5, the bottom chip 12, e.g., the first substrate, may have a topographic structure with two levels, e.g., one level for an elevation and one level for a recess, wherein the top chip 16, e.g., the second substrate, may have a topographic structure with three levels, e.g., one level for an elevation, one level for a recess, and one level for a further recess within the recess. For example, the contacting is provided with one or more superconducting connection layers 14, e.g. made of indium, e.g. for superconducting quantum devices.

Thus, FIG. 5 exemplarily shows a connected/bonded state (see also FIGS. 3d and 4d) with bonded substrates on both sides, e.g. differently and or e.g. multi-level topographically structured, bonded substrates 12, 16 with the different options of the providing the superconducting, mechanically deformable layer 14 (cf. FIGS. 3a-c and FIGS. 4a-c).

FIG. 6 shows a schematic cross sectional view of a substrate structure 10 having a two topographically structured substrates 12, 16 in a connected state according to a further embodiment of the present disclosure.

FIG. 6 shows the schematic representation of a contacted chip-to-chip connection—already mentioned in this description—of an at least single-step (two-level) topographically structured substrate 10 (bottom chip, e.g., first substrate, e.g., having a topographic structure 20 with two levels, one level for an elevation and one level for a recess) with another at least single-step (two-level) topographically structured substrate 16 (top chip, e.g., second substrate, e.g., having a topographic structure with three levels, e.g., one level for an elevation, one level for a recess, and one level for a further recess within the recess) with structured superconducting metallization 26.

For example, the plastically deformable superconductor layer 14 may extend from a parallel surface 20-1 of the topographic structure 20 of the first substrate 12 that has a (e.g., vertical) distance to the main surface 22 of the second substrate 16 that is larger than a smallest (e.g., vertical) distance between the main surfaces 18, 22 of the first and second substrate 12, 16. As can be seen exemplarily in FIG. 6, elevations 20-3, 28-3 from the first and second substrate 12, 16 have a smallest distance relative to each other, which means the elevations 20-3, 28-3 abut against each other first upon movement of the first and second substrate 12, 16 towards each other.

For contacting, a mechanically deformable superconducting connection layer 14, e.g., plastically deformable superconductor layer, e.g. indium, is applied to at least one stepped surface 20-1, 28-1, e.g., a recess. The thickness (e.g., vertical height or offset) of these levels is selected so that (e.g., before compression) at least one of them protrudes beyond the substrate surface (e.g., extends vertically above a height of the elevation of the first substrate 12) or these layers (levels) bond during probing under appropriate conditions (e.g. temperature>melting temperature). Mechanical compression of the two substrates 12, 16 deforms the bonding layer 14 until the substrate surfaces 18, 22 touch, e.g., until surfaces 20-3, 28-3 of the first and second substrate 12, 16 with a smallest distance relative to each other come in mechanical contact, e.g., until the elevations 20-3, 28-3 of the first and second substrate 12, 16 come in mechanical contact. As a result, the superconducting metallizations 24, 26 of the substrates are plane-parallel with simultaneous superconducting contacting 30.

As can be seen in FIG. 6, a height (vertical thickness) of the compressed plastically deformable superconductor layer 14, e.g., of the mechanical and electrical superconductor connection 30, can be controlled by controlling a (vertical) height of the elevations 20-3, 28-3, e.g., the (vertical) height of the mechanical and electrical superconductor connection 30 equals a sum of the (vertical) heights of the elevations 20-3, 28-3. Therefore, control over the height of the mechanical and electrical superconductor connection can be improved.

Thus, FIG. 6 shows a connected/bonded state (see also FIGS. 3d and 4d) with opposing substrates 12, 16, where at least one substrate 12, 16 has a single-step or multi-step (two or more level) structure. The connection 30 is made with one or more superconducting mechanically deformable layers 14, e.g. Indium (see also FIG. 3a-c and FIGS. 4a-c). According to an embodiment, a mechanical compression F to the substrates 12, 16 is applied until the substrate surfaces 18, 22 touch at the elevations 20-3, 28-3. In this FIG. 6, the superconducting compound layer 14 of e.g. indium is located on the first etching stage 20-1, 28-1 of the first and second substrate 12, 16.

As shown in FIG. 6, for example, the two elevations (plateau areas) 20-3, 28-3 of the first substrate 12 and the second substrate 16 do not have superconducting structured metallization, for example, so that no electrical or superconducting connection between the first and second substrates occurs at the mechanical contact areas 20-3, 28-3 between the first and second substrates 12, 16.

The surface areas 20-3, 28-3 of the first and second substrates 12, 16 can also be referred to as plateau areas (plateau regions) of the respective topology of the first and second substrates. As shown in FIG. 6, the (e.g. cured) plastically deformed superconducting layer 30 can maintain the mechanical and electrical (superconducting) connection between the opposing superconducting contact connection surfaces 24, 26 of the first and second substrates 12, 16. In contrast, the contact area of the two plateau areas 20-3, 28-3 of the first and second substrates 12, 16 forms a (mechanical) contact region (interface) in the form of a mechanical stop (abutment), without providing an electrical connection in this (mechanical) contact area, for example. This mechanical stop can be formed and used to adjust the distance and alignment of the two substrates 12, 16, each of which having a respective surface topology. This allows to obtain a distance control and/or orientation control between the first and second substrates 12, 16.

FIGS. 7a-b show schematic cross sectional views of a through-vias 32, 34 of a substrate 12 (16, 44) according to a further embodiment of the present disclosure for providing a through-contacting of chips 12, 16.

TSVs (through silicon vias) 32, 34 can be created using this process, e.g., one or more vias may optionally be provided or formed. FIGS. 7a-b schematically shows the through-contacting of a substrate 12, 16. The substrate topography may be realized by etching on one or both sides, e.g. with KOH or TMAH, and may be used, e.g., to create a TSV (cf. FIG. 7a). Together with a structured superconducting metallization 36, superconducting vias 32, 34 (e.g. superconducting TSVs) can be produced and provided.

As exemplarily shown in FIG. 7a, a through-via 32 of a substrate 12 (16, 44) realized by etching on both sides (front and back of the substrate 12) and superconducting metallization 36. As exemplarily shown in FIG. 7b, the topographically structured substrate surface 18 on one side of the substrate 12 (16, 44) comprises the e.g. superconducting metallization 24 (26) and the superconducting through-via 34.

FIGS. 8a-e show different schematic cross sectional views of connections options of the substrate structure 10 having the (at least two) substrates 12, 16 (16-#) according to a further embodiment of the present disclosure.

As exemplarily shown in FIG. 8a, the (at least two) substrates 12, 16 can be bonded by means of a chip-to-chip-connection (see also FIGS. 2 to 6 an the associated description).

According to an embodiment, as exemplarily shown in FIGS. 8a-e, the method 100 comprises attaching (mechanically coupling/connecting) the first substrate 12 to a first handling wafer 40 before the step 120 of exerting pressure to the first and second substrate 12, 16, and detaching (separating or disconnecting) the first substrate 12 from the first handling wafer 40 after the step 120 of exerting pressure to the first and second substrate 12, 16, and/or attaching (mechanically coupling/connecting) the second substrate 16 to a second handling wafer 42 before the step 120 of exerting pressure to the first and second substrate 12, 16, and detaching (separating or disconnecting) the second substrate 16 from the second handling wafer 42 after the step 120 of exerting pressure to the first and second substrate 12, 16.

According to an embodiment, the first and/or second substrate 12, 16 are respectively temporarily attached/connected to a respective handling wafer 40, 42.

The step 120 of exerting pressure to the first and second substrate 12, 16 may comprise exerting pressure (or force) on one or both of the first and second handing wafers 40, 42. The first and/or second handling wafer 40, 42 may be used for one or more of, flipping a substrate over (e.g., by 180°), arranging the second substrate 16 relative to the first substrate 12, e.g., in a lateral and/or vertical direction, and exerting pressure to the first and second substrate 12, 16.

According to an embodiment, the stack structure 10′ comprises one or more further (second) substrates 16-# (16-1, . . . ) laterally separate from the second substrate 16, wherein each respective further substrate 16-# of the one or more further substrates 16-# has a corresponding main surface 22-# facing the main surface 18 of the first substrate 12, a corresponding structured superconductor metallization 26-# on the corresponding main surface 22-#, and a corresponding plastically deformable superconductor layer 14-# extending between the corresponding structured superconductor metallization 26-# of the respective further (second) substrate 16-# and the structured superconductor metallization 24 of the first substrate 12.

The method 100 further comprises the step 120 of exerting pressure 27 to the first substrate 12 and the one or more further (second) substrates 16-# for respectively compressing, e.g., applying a force F to compress (e.g., to one or both of the first and second substrates 12, 16, e.g., cold-welding) the corresponding further plastically deformable superconductor layer 14-#, e.g., by moving (pressing) the first and further second substrate 12, 16-# towards each other, between the structured superconductor metallizations 24, 26-# of the first and respective further substrate 12, 16-# in order to form a corresponding mechanical and electrical superconductor connection 30, 30-# between the structured superconductor metallizations 24, 26, 26-# of the first substrate 12 and the respective further second substrate 16, 16-#.

According to an embodiment, a plurality of further (second) substrates 16, 16-# are arranged on (e.g., attached to, bonded to, connected with) a common first substrate 12.

For example, the first substrate 12 may be a wafer onto which a plurality of second substrates 16, 16-# are attached. The wafer 12 may optionally be cut (separated or singulated) into a plurality of dices 10, wherein each dice 10 may have one second substrate 16, 16-#(or any other number of second substrates 16, 16-#, such as zero, two, or more).

Thus, as exemplarily shown in FIG. 8b, the (at least two) substrates 12, 16 can be bonded by means of a chip-to-wafer-connection.

As exemplarily shown in FIG. 8c, the (at least two) substrates 12, 16 can be bonded by means of a chip-to-wafer-connection with a one-sided handling wafer 42.

As exemplarily shown in FIG. 8d, the (at least two) substrates 12, 16 can be bonded by means of a chip-to-wafer-connection with a handling wafer 42 on both sides.

As exemplarily shown in FIG. 8e, the (at least two) substrates 12, 16 can be bonded by means of a wafer-to-wafer-connection.

FIG. 9 shows a further schematic cross sectional view of a connections option of the substrate structure 10 having the (at least two) substrates 12, 16 according to further embodiments of the present disclosure.

According to an embodiment, as exemplarily shown in FIG. 9, the main surface 18 of the first substrate 12 comprises a first structured superconductor metallization 24-1 that is electrically isolated from a second structured superconductor metallization 24-2 of the first substrate 12, wherein the first structured superconductor metallization 24-1 of the first substrate 12 laterally overlaps with (vertically opposes), e.g., laterally traverses (e.g., without directly mechanically contacting each other) the structured superconductor metallization 26 of the second substrate 16.

According to an embodiment, the structured superconductor metallization 24 (24-1+24-2) of the first substrate 12, the plastically deformable superconductor layer 14 (e.g., the mechanical and electrical superconductor connection 30 after the step of exerting pressure), and the structured superconductor metallization 26 of the second substrate 16 form a half-bridge (e.g., traversing between the first and second substrate on one first lateral side of the first further structured superconductor metallization, but not necessarily on second lateral side opposite the first lateral side). The half-bridge may allow a lateral overlap (in vertical offset planes) and/or lateral traversal/crossing of the first structured superconductor metallization 24-1 and an conducting lead comprising the half-bridge, e.g., comprising the second structured superconductor metallization 24-2 of the first substrate 12, the plastically deformable superconductor layer 14, and the structured superconductor metallization 26 of the second substrate 16.

FIG. 10 shows a further schematic cross sectional view of a connections option of the substrate structure 10 having the (at least two) substrates 12, 16 according to further embodiments of the present disclosure.

According to an embodiment, as exemplarily shown in FIG. 10 (full-bridge structure), the main surface 18 of the first substrate 12 comprises a third structured superconductor metallization 24-3 that is electrically isolated from the first and second structured superconductor metallization 24-1, 24-2 of the first substrate 12, wherein the first to third structured superconductor metallization 24-1, 24-2, 24-3 form together the structured superconductor metallization 24 of the first substrate 12. The second structured superconductor metallization 24-2 is arranged laterally between the first structured superconductor metallization 24-1 and the third structured superconductor metallization 24-3 of the first substrate 12, wherein the stack structure 10′ comprises a further plastically deformable superconductor layer 14-1 (e.g., electrically isolated from the plastically deformable superconductor layer) that extends between the third structured superconductor metallization 24-3 of the first substrate 12 and the structured superconductor metallization 26 of the second substrate 16.

FIG. 11 shows a further schematic cross sectional view of a connections option of the substrate structure 10 having the (at least two) substrates 12, 16 according to further embodiments of the present disclosure.

According to an embodiment, as exemplarily shown in FIG. 11, the method comprises providing an expanded stack structure 10″ that comprises the first and second substrate 12, 16, e.g. the stack structure 10′ of FIG. 2a or the substrate structure 10 of FIG. 2b (e.g., after the step 120 of exerting force F) with the plastically deformable superconductor layer 14, a third substrate 44, and a second plastically deformable superconductor layer 14-2, wherein the second substrate 16 comprises a backside surface 23 opposite to the main surface 22 of the second substrate 16. The backside surface 23 of the second substrate 16 comprises a backside structured superconductor metallization 27. The third substrate 44 comprises a main surface 46 facing the backside surface 27 of the second substrate 16 and having a structured superconductor metallization 48, wherein the second plastically deformable superconductor layer 14-2 extends between the backside structured superconductor metallization 27 of the second substrate 16 and the structured superconductor metallization 48 of the third substrate 44. The method 100 further comprises the step 120 of exerting pressure 27 to expanded stack structure 10″ (e.g. to the second substrate 16 and the third substrate 16 or between the first substrate 12 and the third substrate 16) for compressing (e.g., applying a force F to compress, e.g., to one or both of the second and third substrate 16, 44 or the first and third substrate 12, 44, e.g., cold-welding) the second plastically deformable superconductor layer 14-2 (e.g., by moving the first and third substrate 12, 44 or the second and third substrate 16, 44 towards each other) between the structured superconductor metallizations 27, 48 of the second and third substrate 16, 44 in order to form a mechanical and electrical superconductor connection 30-2 between the structured superconductor metallizations 27, 48 of the second substrate 16 and the third substrate 44.

In the embodiment of substrate structure 10 shown in FIG. 11 with the first to third substrates (or further substrates) 12, 16, 44, it should be noted that each of the substrates may have a topography on at least one of the two main surface areas, as already described for the individual substrates in the above described embodiments. Furthermore, each of the substrates may also have so-called TSVs (TSV=through-silicon via) for providing (if necessary) electrical and/or superconducting through-connections (feedthroughs) between electrical and/or superconducting contact areas on opposite main surface areas of the respective substrate.

Furthermore, all of the embodiments and options described above for the design of the individual substrates, structured metallizations, plastically deformable superconductor layers, feedthroughs, connections, substrate topologies, TSVs, etc., are also respectively applicable to each of the substrates 12, 16, 44 shown in FIG. 11 or any further connected substrate(s).

FIG. 12 shows a schematic cross sectional view of a substrate structure 10 having two substrates 12, 16 in a connected state according to a further embodiment of the present disclosure.

According to an embodiment, as exemplarily shown in FIG. 12, a substrate structure 10 comprises a stack structure 10′ comprising a first substrate 12 (e.g., silicon substrate), a plastically deformable superconductor layer 14 (e.g., comprising or consisting of indium), and a second substrate 16 (e.g., silicon substrate). The first substrate 12 has a main surface 18 with a topographic structure 20 and the second substrate 16 (e.g., silicon substrate) has a main surface 22 facing the main surface 18 of the first substrate 16. According to an embodiment, the main surface 22 of the second substrate 16 may (optionally) also have a topographic structure 28.

The main surface 18 and e.g., at least a portion of the topographic structure 20 of the first substrate 12 comprises a structured superconductor metallization 24, e.g., comprising one or more of following materials: Al, Nb, Ta, TiN, and the main surface 22 of the second substrate 16 comprises a structured superconductor metallization 26, e.g., comprising one or more of the following materials: Al, Nb, Ta, TiN, and a (compressed) plastically deformable superconductor layer 14 (e.g., which is compressed by moving the first and second substrate 12, 16 towards each other). The plastically deformable superconductor layer 14 extends between the structured superconductor metallizations 24, 26 of the first and second substrates 12, 16 in order to provide a mechanical and electrical superconductor connection 30 between the structured superconductor metallizations 24, 26 of the first and second substrates 12, 16.

The substrate structure 10 may be formed by any method disclosed herein. Therefore, the substrate structure 10 may comprise any feature disclosed herein with reference any method disclosed herein, e.g., comprising one or more of multi-layered structures, vias, a half-bridge, a full bridge, the being arranged on a recess and/or an elevation.

This bonding process (method) 100 described here in combination with at least one topographically structured substrate 12, 16 enables the 3D structure described above with two or more chips 12, 16 of the same or different dimensions. Other possible applications include integration in chiplet systems or 3D stacking.

In the following, further embodiments of the present disclosure a generally described and are applicable to the above described embodiments of the substrate structure 10 and the method 100 for fabricating such a substrate structure 10.
Topographically structured silicon with mostly atomically smooth surfaces of the (111) plane, e.g., by KOH or TMAH etching in connection with the bonding processes mentioned in this document (see FIG. 7), e.g. for qubit applications.
Topographically structured silicon with the surface texture typically etched by KOH or TMAH etching in connection with the bonding processes mentioned here (FIG. 7) (e.g. for qubit applications).
Improvement of the quality factors of topographically structured substrates, e.g., by thermal oxidation and/or annealing processes.
Deposition and structuring with lithographic processes, e.g., of conductive or superconductive metallic single layers and/or layer sequences on the topographically structured substrate (e.g., of one or more of structured superconductor metallization and plastically deformable superconductor layer).
For contacts (e.g., mechanical and electrical superconductor connection) between two or more chips (e.g., two or more substrates), single or multi-level pillars (e.g., elevations of multi-layered topographic structures) are created, e.g., on one or more chips and structured with metal (e.g., forming structured superconductor metallization).
Crossing of conductor paths (e.g., of superconducting leads comprising metallizations of the first and second substrate) by using at least one etched, topographically metallized-structured substrate with at least one further metallized-structured substrate connected via the superconducting connecting material (e.g. indium). For example, a first further structured superconductor metallization of the first substrate may laterally overlap or traverse a superconducting lead comprising the structured superconductor metallization by (e.g., vertically) traversing to the second substrate via the mechanical and electrical superconductor connection. The superconducting lead may optionally traverse back to the first substrate via a further mechanical and electrical superconductor connection formed by compressing a further plastically deformable superconductor layer between the structured superconductor metallization of the second substrate and a second further structured superconductor metallization of the first substrate. In other words, the superconducting lead may cross or laterally travers the first further structured superconductor metallization using a bridge with two vertical mechanical and electrical superconductor connections and the structured superconductor metallization of the second substrate, which can laterally cross or travers the first further structured superconductor metallization.
Deposition of, e.g. superconductive, layers may be carried out using chemical, electrochemical or physical deposition processes (e.g., any deposition process disclosed herein).
For superconducting contacts (e.g., mechanical and electrical superconductor connections), e.g., a superconducting seed layer (e.g. Ti for alpha Ta) may be applied and a superconducting mechanically deformable connecting layer (e.g. In) may be applied thereon.
For superconducting contacts (e.g., mechanical and electrical superconductor connections), e.g., a superconducting seed layer (e.g. Ti for alpha Ta) or a superconducting mechanically deformable connecting layer (e.g. In) may be applied and these layers may be structured (e.g., using a lithographic structuring process, may have identical lateral structures, e.g., using the same structured photoresist layer), for example.
For superconducting contacts (e.g., mechanical and electrical superconductor connections), e.g., a superconducting intermediate layer (e.g. Nb or TiN) and a superconducting mechanically deformable connecting layer (e.g. In) may be applied and these layers may be structured differently (e.g., by forming two different structured photoresist layers), for example.
Among others, these layers (e.g., plastically deformable superconductor layer, e.g., layers and/or portions thereof) may be located on the lower level (e.g., recess of multi-layered topographic structures) of single or multi-level pillars of two or more of the substrates to be bonded. The layer thickness (e.g., of the uncompressed plastically deformable superconductor layer) is selected so that it protrudes above the top level overall (e.g., vertically extends above the elevation, e.g., vertically extends so far that the second substrate contacts the plastically deformable superconductor layer first upon movement towards the first substrate). For example, by mechanically pressing in one of the joining methods mentioned in this document, the deformable superconducting layer is compressed until the two upper substrate surfaces (e.g. silicon) of the pillars touch each other (FIG. 5). This results in a superconducting contact and precise distance control and plane parallelism of the layers.
These layers (e.g., plastically deformable superconductor layer, e.g., layers and/or portions thereof) may be located on the surface of the single-step (two-level), two-step (three-level) or multi-step (multi-level) pillars on one or both of the chips to be connected (e.g., on elevations, e.g., of multi-layer topographic structures, on surfaces with a smallest distance between the first and second substrate). By mechanically pressing, e.g. during the flip-chip process, wafer bonding or other bonding methods mentioned in this document, these layers come into contact (e.g., a contact between the plastically deformable superconductor layer and the structured superconductor metallizations of the first and second substrate, e.g., a contact between a portion and a further portion of the plastically deformable superconductor layer respectively formed on the structured superconductor metallizations of the first and second substrate), the superconducting mechanically deformable bonding layer may be compressed at the pressure points (e.g., at regions of the main surfaces that compress the plastically deformable superconductor layer, e.g., wherein the first and second substrate only come in mechanical contact at regions that sandwich the plastically deformable superconductor layer), and a superconducting contact (e.g., mechanical and electrical superconductor connection) is created (FIGS. 2, 3, 4, 5).
Connecting two or more chips (e.g., first and second substrate) may be done using flip-chip technology (FIG. 7a).
Connecting one or more chips (e.g., one or more second substrates) on a wafer (e.g., a first substrate, e.g., a common first substrate) may be done using chip-to-wafer technology (FIG. 7b).
Connecting chips (e.g., first substrate) placed on (e.g., attached to) a handling wafer to another wafer (e.g., second substrate) (chips are located between the two wafers) may be done using wafer-to-wafer technology (FIG. 7c).
Connecting chips (e.g., one or more first substrates) placed on a handling wafer to chips (e.g., one or more second substrates) also placed on a handling wafer may be done using wafer-to-wafer technology (FIG. 7d).
Connecting a wafer to another wafer may be done using wafer-to-wafer technology (FIG. 7e).
Precise adjustment of the distances between e.g. two or more substrates (e.g., a height of a mechanical and electrical superconductor connection) may be done via arbitrarily structured stepped pillars (e.g., forming a multi-layer topographic structure with controlled height difference between two or more layers), e.g., created by KOH or TMAH etching and may be connected to a conductive or superconducting material (e.g. indium) (e.g., by forming the plastically deformable superconductor layer on structured superconductor metallizations of the first and second substrate which have a larger distance than a shortest distance between the first and second substrate).
Precise adjustment of identical or different distances (etch depths) for different applications (e.g. crossings of conductor paths, vertical coupling of microwave fields and contacting of chips).
Vertical coupling of microwave fields by a design with suitable spacing (etching depths).
Crossings through defined or defined-different or different etching depths.
Couplings through defined or defined-different or different etching depths.
Stacking of chips may be done by structuring and contacting on both sides (e.g., attaching a third substrate on a backside surface of the second substrate).
If the substrate is structured on both sides (e.g., on the main surface and the backside surface), the second side (e.g., backside surface) may be structured before or after completion of the first side or at the same time (see FIG. 6).
A through-etch (e.g., via) may be created by structuring both sides of the substrate from a chip (see FIG. 6) or structuring only one side.
TSVs (Through Silicon Vias), e.g., may be created by structuring both sides of the substrate of a chip (see FIG. 6) or structuring only one side.
By structuring the substrate on both sides, e.g., a superconducting through-contacting or superconducting TSVs (Through Silicon Vias) may be produced (see FIG. 6).
The bonding methods mentioned in this document may be combined with the topographies created by etching (e.g. through-contacting) mentioned here.
The bonding methods mentioned in this document may be carried out at any temperature (e.g. room temperature).
The bonding methods mentioned in this document can be carried out under normal and protective atmospheres.

Embodiments of the present disclosure are generally applicable to the following technical fields of application: Connection of quantum components of two or more chips/components, e.g. mechanical connection, electrical connection, superconductive connection, capacitive coupling, thermal coupling, etc.

Embodiments of the present disclosure generally allow to realize the following technical implementations and effects:
Crossings of conductor paths (bridging by means of a topographically structured substrate and a contact across two or more chips)
Vertical capacitive coupling
Combinations of vias or TSVs with topographical, e.g. metallized, structuring.
3D structure (including stacking of two or more structured or unstructured substrates with through-contactings, for example)
Increased design flexibility
The process may use any metal with which an ohmic or superconducting contact can be made (e.g. alloy contact) or the native oxide of the metals can be removed.
For example, the bonding surface is located exclusively on the pillars, and the resulting cavity between the same allows particles and impurities to pass through. This ensures that the bonded substrates are parallel to each other.
Due to the topographically structured silicon surface, only the indium serves as an adhesive surface, e.g. on the raised bond interfaces (pillars). The etched surface next to these pillars has a greater distance to the bonding partner. The resulting distance between the bonding surfaces provides space for structures for capacitive coupling, for example. The force entailed for probing can be reduced due to the reduced bonding surface while maintaining the same bonding pressure.

Additional embodiments and aspects are described which may be used alone or in combination with the features and functionalities described herein.

According to an embodiment, a method for fabricating a substrate structure may have the steps of: providing a stack structure comprising a first substrate, a plastically deformable superconductor layer, and a second substrate, wherein the first substrate has a main surface with a topographic structure and the second substrate has a main surface facing the main surface of the first substrate, wherein the main surface of the first substrate comprises a structured superconductor metallization and the main surface of the second substrate comprises a structured superconductor metallization, wherein the plastically deformable superconductor layer extends between the structured superconductor metallization of the first substrate and the structured superconductor metallization of the second substrate, and exerting pressure to the first and second substrate for compressing the plastically deformable superconductor layer between the structured superconductor metallizations of the first and second substrates in order to form a mechanical and electrical superconductor connection between the structured superconductor metallizations of the first and second substrates.

According to another embodiment, the main surface of the second substrate may comprise a topographic structure.

According to another embodiment, the plastically deformable superconductor layer may extend (be arranged) between two surfaces of the structured superconductor metallizations of the first and second substrates that are parallel to each other.

According to another embodiment, at least one respective topographic structure of the first and second substrates may have a multilevel structure, in which parallel surfaces of the respective topographic structure are arranged at different heights (levels or planes) relative to each other.

According to another embodiment, the plastically deformable superconductor layer may extend between a parallel surface of the topographic structure of the first substrate that has a smallest distance to the main surface of the second substrate.

According to another embodiment, the plastically deformable superconductor layer may extend from a parallel surface of the topographic structure of the first substrate that has a distance to the main surface of the second substrate that is larger than a smallest distance between the main surfaces of the first and second substrate.

According to another embodiment, providing the stack structure may comprise at least one of forming the topographic structure of the main surface of the first substrate using etching, and forming the topographic structure of the second main surface using etching.

According to another embodiment, the first substrate may comprise monocrystalline silicon with a (100)-silicon surface and forming the topographic structure of the first substrate comprises forming {111}-planes using anisotropic etching, and/or the second substrate comprises monocrystalline silicon with a (100)-silicon surface and forming the topographic structure of the second substrate comprises forming {111}-planes using anisotropic etching.

According to another embodiment, providing the stack structure may comprise at least one of forming the structured superconductor metallization on the main surface of the first substrate using a lithographic fabrication process, and forming the structured superconductor metallization on the main surface of the second substrate using a lithographic fabrication process.

According to another embodiment, forming the structured superconductor metallization of the first and/or second substrate may comprise depositing a nucleation layer on the corresponding main surface, and depositing a superconductor metal on the nucleation layer.

According to another embodiment, providing the stack structure may comprise one of forming the plastically deformable superconductor layer on the structured superconductor metallization of the first substrate; forming the plastically deformable superconductor layer on the second structured superconductor metallization; and forming a first portion of the plastically deformable superconductor layer on the structured superconductor metallization of the first substrate and a second portion of the plastically deformable superconductor layer on the structured superconductor metallization of the second substrate, and mechanically contacting the first and second portion of the plastically deformable superconductor layer to form the plastically deformable superconductor layer.

According to another embodiment, the method may further comprise heating the plastically deformable superconducting layer between the structured superconducting metallizations of the first and second substrate before and/or during the step of exerting pressure the first and second substrates.

According to another embodiment, the plastically deformable superconductor layer may comprise or consist of an electrically conductive and superconductive paste, wherein the method may further comprise curing the plastically deformed superconducting layer between the structured superconducting metallizations of the first and second substrates after the step of exerting pressure the first and second substrates.

According to another embodiment, the plastically deformable superconductor layer may comprises indium, and/or one or more structured superconductor metallizations of the first and/or second substrate comprise one or more of niobium, aluminum, tantalum, titanium nitride, and indium.

According to another embodiment, the main surface of the first substrate may comprise a first structured superconductor metallization that is electrically isolated from a second structured superconductor metallization of the first substrate, wherein the first structured superconductor metallization of the first substrate laterally overlaps with the structured superconductor metallization of the second substrate.

According to another embodiment, the main surface of the first substrate may comprise a third structured superconductor metallization that is electrically isolated from the (first) structured superconductor metallization and the second structured superconductor metallization of the first substrate, wherein the (first) structured superconductor metallization is arranged laterally between the second structured superconductor metallization and the third structured superconductor metallization of the first substrate, wherein the stack structure comprises a further plastically deformable superconductor layer that extends between the third structured superconductor metallization of the first substrate and the structured superconductor metallization of the second substrate, wherein exerting pressure to the first and second substrate may comprise compressing the further plastically deformable superconductor layer between the third structured superconductor metallization of the first substrate and the structured superconductor metallization of the second substrate in order to form a further mechanical and electrical superconductor connection between the third structured superconductor metallization of the first substrate and the structured superconductor metallization of the second substrate.

According to another embodiment, the method may further comprise at least one of forming the second structured superconductor metallization on the first main surface using a lithographic fabrication process, forming the third structured superconductor metallization on the first main surface using a lithographic fabrication process, forming the further plastically deformable superconductor layer or a first portion thereof on the second further structured superconductor metallization of the first substrate; and forming the further plastically deformable superconductor layer or a second portion thereof on the structured superconductor metallization of the second substrate.

According to another embodiment, the stack structure may comprise at least one of a via extending through the first substrate and a superconductor connection through the via of the first substrate that electrically and superconducting connects a portion of first main surface of the first substrate with a portion of a backside surface of the first substrate that is opposite of the main surface, a further via extending through the second substrate and a superconductor connection through the via of the second substrate that electrically and superconducting connects a portion of the main surface of the second substrate with a portion of a backside surface of the second substrate that is opposite of the main surface of the second substrate.

According to another embodiment, the method may comprise forming the via of the first substrate using etching the first substrate and forming a superconductor material in the via of the first substrate, and/or forming the further via of the second substrate using etching the second substrate and forming a superconductor material in the further via of the second substrate.

According to another embodiment, the method may comprise attaching the first substrate to a first handling wafer before the step of exerting pressure to the first and second substrate, and detaching the first substrate from the first handling wafer after the step of exerting pressure to the first and second substrate, and/or attaching the second substrate to a second handling wafer before the step of exerting pressure to the first and second substrate, and detaching the second substrate from the second handling wafer after the step of exerting pressure to the first and second substrate.

According to another embodiment, the stack structure may comprise one or more further substrates laterally separate from the second substrate, wherein each respective further substrate has a corresponding main surface facing the main surface of the first substrate, a corresponding structured superconductor metallization on the corresponding main surface, and a corresponding plastically deformable superconductor layer extending between the corresponding structured superconductor metallization of the respective further second substrate and the structured superconductor metallization of the first substrate, wherein the method may further comprise exerting (mechanical) pressure to the first substrate and each further substrate for respectively compressing the corresponding further plastically deformable superconductor layer between the structured superconductor metallizations of the first and the respective further substrate in order to form a corresponding mechanical and electrical superconductor connection between the structured superconductor metallizations of the first substrate and the respective further substrate.

According to another embodiment, the method may comprise providing an expanded stack structure that comprises the substrate structure, a third substrate, and a second plastically deformable superconductor layer, wherein the second substrate comprises a backside surface opposite the main surface of the second substrate and the backside surface comprises a backside structured superconductor metallization, wherein the third substrate comprises a main surface facing the backside surface of the second substrate and having a structured superconductor metallization, wherein the second plastically deformable superconductor layer extends between the backside structured superconductor metallization of the second substrate and the structured superconductor metallization of the third substrate, and exerting pressure to the second substrate and the third substrate for compressing the second plastically deformable superconductor layer between the structured superconductor metallizations of the second and third substrate in order to form a mechanical and electrical superconductor connection between the structured superconductor metallizations of the second substrate and the third substrate.

According to another embodiment, a substrate structure may comprise a stack structure comprising a first substrate, a plastically deformable superconductor layer, and a second substrate, wherein the first substrate has a main surface with a topographic structure and the second substrate has a main surface facing the main surface of the first substrate, wherein the main surface of the first substrate comprises a structured superconductor metallization and the main surface of the second substrate comprises a structured superconductor metallization, and a compressed plastically deformable superconductor layer extending between the structured superconductor metallizations of the first and second substrates in order to provide a mechanical and electrical superconductor connection between the structured superconductor metallizations of the first and second substrates.

According to another embodiment, the stack structure may comprise one or more further second substrates laterally separated from the second substrate, wherein each respective further second substrate of the one or more further second substrate has a corresponding main surface facing the main surface of the first substrate, a corresponding structured superconductor metallization on the corresponding main surface, and a corresponding plastically deformable superconductor layer extending between the corresponding structured superconductor metallization of the respective further second substrate and the structured superconductor metallization of the first substrate, and one or more compressed corresponding further plastically deformable superconductor layers respectively extending between the structured superconductor metallizations of the first substrate and the corresponding structured superconductor metallization of the respective further second substrate in order to provide a corresponding mechanical and electrical superconductor connection between the structured superconductor metallizations of the first substrate and the corresponding structured superconductor metallization of the respective further second substrate.

According to another embodiment, the stack structure may further comprise: a third substrate, wherein the second substrate comprises a backside surface opposite the main surface of the second substrate and the backside surface comprises a backside structured superconductor metallization, wherein the third substrate comprises a main surface facing the backside surface of the second substrate and having a structured superconductor metallization, and a second compressed plastically deformable superconductor layer extending between the structured superconductor metallizations of the second and third substrates in order to provide a second mechanical and electrical superconductor connection between the structured superconductor metallizations of the second and third substrates.

Although some aspects have been described as features in the context of an apparatus, it is clear that such a description may also be regarded as a description of corresponding features of a method. Although some aspects have been described as features in the context of a method, it is clear that such a description may also be regarded as a description of corresponding features concerning the functionality of an apparatus.

Depending on certain implementation requirements, embodiments of the control circuitry can be implemented in hardware or in software or at least partially in hardware or at least partially in software. Generally, embodiments of the control circuitry can be implemented as a computer program product with a program code, the program code being operative for performing one of the methods when the computer program product runs on a computer. The program code may, for example, be stored on a machine-readable carrier.

In the foregoing detailed description, it can be seen that various features are grouped together in examples for the purpose of streamlining the disclosure. This method of disclosure is not to be interpreted as reflecting an intention that the claimed examples require more features than are expressly recited in each claim. Rather, as the following claims reflect, subject matter may lie in less than all features of a single disclosed example. Thus, the following claims are hereby incorporated into the detailed description, where each claim may stand on its own as a separate example. While each claim may stand on its own as a separate example, it is to be noted that, although a dependent claim may refer in the claims to a specific combination with one or more other claims, other examples may also include a combination of the dependent claim with the subject matter of each other dependent claim or a combination of each feature with other dependent or independent claims. Such combinations are proposed herein unless it is stated that a specific combination is not intended. Furthermore, it is intended to include also features of a claim to any other independent claim even if this claim is not directly made dependent to the independent claim.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

I/We claim:

1. A method for fabricating a substrate structure, comprising:
providing a stack structure comprising a first substrate, a plastically deformable superconductor layer, and a second substrate, wherein the first substrate comprises a main surface with a topographic structure and the second substrate comprises a main surface facing the main surface of the first substrate, wherein the main surface of the first substrate comprises a structured superconductor metallization and the main surface of the second substrate comprises a structured superconductor metallization, wherein the plastically deformable superconductor layer extends between the structured superconductor metallization of the first substrate and the structured superconductor metallization of the second substrate, and
exerting pressure to the first and second substrate for compressing the plastically deformable superconductor layer between the structured superconductor metallizations of the first and second substrates in order to form a mechanical and electrical superconductor connection between the structured superconductor metallizations of the first and second substrates.

2. The method according to claim 1, wherein the main surface of the second substrate comprises a topographic structure.

3. The method according to claim 1, wherein the plastically deformable superconductor layer extends (is arranged) between two surfaces of the structured superconductor metallizations of the first and second substrates that are parallel to each other.

4. The method according to claim 1, wherein at least one respective topographic structure of the first and second substrates comprises a multilevel structure, in which parallel surfaces of the respective topographic structure are arranged at different heights (levels or planes) relative to each other.

5. The method according to claim 4, wherein the plastically deformable superconductor layer extends between a parallel surface of the topographic structure of the first substrate that comprises a smallest distance to the main surface of the second substrate.

6. The method according to claim 4, wherein the plastically deformable superconductor layer extends from a parallel surface of the topographic structure of the first substrate that comprises a distance to the main surface of the second substrate that is larger than a smallest distance between the main surfaces of the first and second substrate.

7. The method according to claim 1, wherein providing the stack structure comprises at least one of
forming the topographic structure of the main surface of the first substrate using etching, and
forming the topographic structure of the second main surface using etching.

8. The method according to claim 7, wherein
the first substrate comprises monocrystalline silicon with a (100)-silicon surface and forming the topographic structure of the first substrate comprises forming {111}-planes using anisotropic etching,
and/or
the second substrate comprises monocrystalline silicon with a (100)-silicon surface and forming the topographic structure of the second substrate comprises forming {111}-planes using anisotropic etching.

9. The method according to claim 1,
wherein providing the stack structure comprises at least one of
forming the structured superconductor metallization on the main surface of the first substrate using a lithographic fabrication process, and
forming the structured superconductor metallization on the main surface of the second substrate using a lithographic fabrication process.

10. The method according to claim 9, wherein
forming the structured superconductor metallization of the first and/or second substrate comprises:
depositing a nucleation layer on the corresponding main surface, and
depositing a superconductor metal on the nucleation layer.

11. The method according to claim 1,
wherein providing the stack structure comprises one of
forming the plastically deformable superconductor layer on the structured superconductor metallization of the first substrate;
forming the plastically deformable superconductor layer on the second structured superconductor metallization; and
forming a first portion of the plastically deformable superconductor layer on the structured superconductor metallization of the first substrate and a second portion of the plastically deformable superconductor layer on the structured superconductor metallization of the second substrate, and mechanically contacting the first and second portion of the plastically deformable superconductor layer to form the plastically deformable superconductor layer.

12. The method according to claim 1, further comprising:
heating the plastically deformable superconducting layer between the structured superconducting metallizations of the first and second substrate before and/or during exerting pressure the first and second substrates.

13. The method according to claim 1, wherein the plastically deformable superconductor layer comprises or consists of an electrically conductive and superconductive paste, further comprising:
curing the plastically deformed superconducting layer between the structured superconducting metallizations of the first and second substrates after exerting pressure the first and second substrates.

14. The method according to claim 1,
wherein the plastically deformable superconductor layer comprises indium, and/or
one or more structured superconductor metallizations of the first and/or second substrate comprise one or more of niobium, aluminum, tantalum, titanium nitride, and indium.

15. The method according to claim 1, wherein the main surface of the first substrate comprises a first structured superconductor metallization that is electrically isolated from a second structured superconductor metallization of the first substrate, wherein the first structured superconductor metallization of the first substrate laterally overlaps with the structured superconductor metallization of the second substrate.

16. The method according to claim 15,
wherein the main surface of the first substrate comprises a third structured superconductor metallization that is electrically isolated from the (first) structured superconductor metallization and the second structured superconductor metallization of the first substrate, wherein the (first) structured superconductor metallization is arranged laterally between the second structured superconductor metallization and the third structured superconductor metallization of the first substrate,
wherein the stack structure comprises a further plastically deformable superconductor layer that extends between the third structured superconductor metallization of the first substrate and the structured superconductor metallization of the second substrate,
wherein exerting pressure to the first and second substrate comprises:
compressing the further plastically deformable superconductor layer between the third structured superconductor metallization of the first substrate and the structured superconductor metallization of the second substrate in order to form a further mechanical and electrical superconductor connection between the third structured superconductor metallization of the first substrate and the structured superconductor metallization of the second substrate.

17. The method according to claim 15,
further comprising at least one of
forming the second structured superconductor metallization on the first main surface using a lithographic fabrication process,
forming the third structured superconductor metallization on the first main surface using a lithographic fabrication process,
forming the further plastically deformable superconductor layer or a first portion thereof on the second further structured superconductor metallization of the first substrate; and
forming the further plastically deformable superconductor layer or a second portion thereof on the structured superconductor metallization of the second substrate.

18. The method according to claim 1,
wherein the stack structure comprises at least one of
a via extending through the first substrate and a superconductor connection through the via of the first substrate that electrically and superconducting connects a portion of first main surface of the first substrate with a portion of a backside surface of the first substrate that is opposite of the main surface,
a further via extending through the second substrate and a superconductor connection through the via of the second substrate that electrically and superconducting connects a portion of the main surface of the second substrate with a portion of a backside surface of the second substrate that is opposite of the main surface of the second substrate.

19. The method according to claim 18, comprising
forming the via of the first substrate using etching the first substrate and forming a superconductor material in the via of the first substrate,
and/or
forming the further via of the second substrate using etching the second substrate and forming a superconductor material in the further via of the second substrate.

20. The method according to claim 1, comprising
attaching the first substrate to a first handling wafer before exerting pressure to the first and second substrate, and
detaching the first substrate from the first handling wafer after exerting pressure to the first and second substrate, and/or
attaching the second substrate to a second handling wafer before exerting pressure to the first and second substrate, and
detaching the second substrate from the second handling wafer after exerting pressure to the first and second substrate.

21. The method according to claim 1,
wherein the stack structure comprises one or more further substrates laterally separate from the second substrate, wherein each respective further substrate comprises a corresponding main surface facing the main surface of the first substrate, a corresponding structured superconductor metallization on the corresponding main surface, and a corresponding plastically deformable superconductor layer extending between the corresponding structured superconductor metallization of the respective further second substrate and the structured superconductor metallization of the first substrate,
the method further comprising
exerting (mechanical) pressure to the first substrate and each further substrate for respectively compressing the corresponding further plastically deformable superconductor layer between the structured superconductor metallizations of the first and the respective further substrate in order to form a corresponding mechanical and electrical superconductor connection between the structured superconductor metallizations of the first substrate and the respective further substrate.

22. The method according to claim 1, comprising
providing an expanded stack structure that comprises the substrate structure, a third substrate, and a second plastically deformable superconductor layer, wherein the second substrate comprises a backside surface opposite the main surface of the second substrate and the backside surface comprises a backside structured superconductor metallization, wherein the third substrate comprises a main surface facing the backside surface of the second substrate and having a structured superconductor metallization, wherein the second plastically deformable superconductor layer extends between the backside structured superconductor metallization of the second substrate and the structured superconductor metallization of the third substrate, and
exerting pressure to the second substrate and the third substrate for compressing the second plastically deformable superconductor layer between the structured superconductor metallizations of the second and third substrate in order to form a mechanical and electrical superconductor connection between the structured superconductor metallizations of the second substrate and the third substrate.

23. A substrate structure comprising,
a stack structure comprising a first substrate, a plastically deformable superconductor layer, and a second substrate, wherein the first substrate comprises a main surface with a topographic structure and the second substrate comprises a main surface facing the main surface of the first substrate, wherein the main surface of the first substrate comprises a structured superconductor metallization and the main surface of the second substrate comprises a structured superconductor metallization, and
a compressed plastically deformable superconductor layer extending between the structured superconductor metallizations of the first and second substrates in order to provide a mechanical and electrical superconductor connection between the structured superconductor metallizations of the first and second substrates.

24. The substrate structure according to claim 23,
wherein the stack structure comprises one or more further second substrates laterally separated from the second substrate, wherein each respective further second substrate of the one or more further second substrate comprises a corresponding main surface facing the main surface of the first substrate, a corresponding structured superconductor metallization on the corresponding main surface, and a corresponding plastically deformable superconductor layer extending between the corresponding structured superconductor metallization of the respective further second substrate and the structured superconductor metallization of the first substrate, and
one or more compressed corresponding further plastically deformable superconductor layers respectively extending between the structured superconductor metallizations of the first substrate and the corresponding structured superconductor metallization of the respective further second substrate in order to provide a corresponding mechanical and electrical superconductor connection between the structured superconductor metallizations of the first substrate and the corresponding structured superconductor metallization of the respective further second substrate.

25. The substrate structure of claim 23, further comprising:
a third substrate, wherein the second substrate comprises a backside surface opposite the main surface of the second substrate and the backside surface comprises a backside structured superconductor metallization, wherein the third substrate comprises a main surface facing the backside surface of the second substrate and having a structured superconductor metallization, and
a second compressed plastically deformable superconductor layer extending between the structured superconductor metallizations of the second and third substrates in order to provide a second mechanical and electrical superconductor connection between the structured superconductor metallizations of the second and third substrates.
